(19) United States
(12) Patent Application Publication
(10) Pub. No.: US 2013/0083265 A1
(43) Pub. Date: Apr. 4, 2013

(54) ACTIVE MATRIX SUBSTRATE, METHOD FOR FABRICATING THE SAME, AND LIQUID CRYSTAL DISPLAY PANEL

(71) Applicant: Katsunori Misaki, Yonago-shi (JP)

(72) Inventor: Katsunori Misaki, Yonago-shi (JP)

(21) Appl. No.: 13/702,101

(22) PCT Filed: May 20, 2011
(86) PCT No.: PCT/JP2011/002824

§ 371 Date: Dec. 5, 2012

(30) Foreign Application Priority Data
Jul. 21, 2010 (JP) 2010-163639

(51) Int. Cl. H01L 27/15; H01L 21/8232; G02F 1/1368

(52) U.S. Cl. CPC H01L 27/15; G02F 1/1368; H01L 21/8232
USPC 349/42; 257/59; 257/72; 438/34

(57) ABSTRACT

An active matrix substrate (30a) includes a plurality of switching elements (5a), a first protective insulating film (20a) provided on the plurality of switching elements (5a), a transparent conductive layer (21b) provided on the first protective insulating film (20a), a second protective insulating film (22a) provided on the transparent conductive layer (21b), and a plurality of pixel electrodes (23a) on the second protective insulating film (22a), wherein a groove (G) is formed in the second protective insulating film (22a) along a vicinity of a corresponding one of the plurality of pixel electrodes (23a) so that part of the first protective insulating film (20a) is exposed, and the transparent conductive layer (21b) is provided along the groove (G) of the second protective insulating film (22a) to be exposed from a sidewall (W) of the groove (G) while being recessed from the sidewall (W) of the groove (G).

### TECHNICAL FIELD

The present invention relates to active matrix substrates, methods for fabricating such active matrix substrates, and liquid crystal display panels, and in particular, relates to techniques for reducing or preventing a short circuit between a plurality of pixel electrodes provided in the active matrix substrate.

### BACKGROUND ART

An liquid crystal display panel of an active matrix drive type includes an active matrix substrate in which a switching element, such as a thin film transistor (hereinafter referred to as a “TFT”) etc., is provided in each pixel which is the smallest unit of an image, a counter substrate disposed to face the active matrix substrate, and a liquid crystal layer enclosed between the both substrates.

In the active matrix substrate, a plurality of pixel electrodes are arranged in an matrix pattern with narrow intervals, and therefore, particles occur in a step of forming a transparent conductive film serving as respective pixel electrodes, and in a step of patterning the transparent conductive film by photolithography etc., and if the particles adhere to the substrate, this may cause a short circuit between adjoining ones of pixel electrodes.

For example, Patent Document 1 discloses a method for fabricating a TFT matrix, the method including the steps of forming a protective insulating film on a substrate having a plurality of TFTs thereon, forming a groove in a region of the protective insulating film serving as a separation region between adjoining ones of pixel electrodes and simultaneously forming an opening in the protective insulating film on a source electrode of each of the TFTs, forming a transparent conductive film on the entire surface, and selectively etching the transparent conductive film to separate it in each pixel region by the groove, and forming the pixel electrodes each connected to the source electrode of each of the TFTs through the opening. According to the method for fabricating the TFT matrix in the Patent Document 1, after forming the groove in the region of the protective insulating film serving as a separation region between adjoining ones of the pixel electrodes, the transparent conductive film is formed on the entire surface, and therefore, the thickness of part of the transparent conductive film located on the sidewall of the groove is thinner than that of part of the transparent conductive film located on a flat surface, and when the part of the transparent conductive film located on the flat surface is removed by etching, the part of the transparent conductive film located on the sidewall of the groove is reliably removed, and even if foreign substances fill the groove, according to wet etching, etching liquid flows through the groove continuously formed under the foreign substances to remove transparent electrodes under the foreign substances, thereby making it possible to completely separate the pixel electrodes from each other so that each of the pixel electrodes is provided in each pixel region.

### CITATION LIST

### Patent Document

PATENT DOCUMENT 1: Japanese Patent Publication No. H08-106107

### SUMMARY OF THE INVENTION

### Technical Problem

According to the fabrication method disclosed in Patent Document 1, if the groove formed in the protective insulating film has an inverted tapered shape, the transparent conductive film is more likely to be formed on the sidewall of the groove depending on conditions for forming the transparent conductive film (for example, low pressure of approximately 0.2 Pa), and if the transparent conductive film located in the groove cannot be completely removed, a short circuit may occur between the adjoining ones of the pixel electrodes, and this method has room for improvement.

In view of the foregoing, the present invention has been achieved. It is an object of the present invention to reliably reduce or prevent a short circuit between adjoining pixel electrodes.

### Solution to the Problem

In order to attain the above object, according to the present invention, a transparent conductive layer disposed between a first protective insulating film located above respective switching elements and a second protective insulating film located under respective pixel electrodes is provided along a groove of the second protective insulating film to be exposed from a sidewall of the groove while being recessed from the sidewall of the groove.

Specifically, an active matrix substrate according to the present invention includes a plurality of pixels arranged in an matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in an matrix pattern on the second protective insulating film, and each connected to a corresponding one of the plurality of switching elements, wherein a groove is formed in the second protective insulating film along a vicinity of a corresponding one of the plurality of pixel electrodes so that part of the first protective insulating film is exposed, and the transparent conductive layer is provided along the groove of the second protective insulating film to be exposed from a sidewall of the groove while being recessed from the sidewall of the groove.

According to the above configuration, the groove is formed in the second protective insulating film located under the pixel electrodes along the vicinity of each of the pixel electrodes so that the first protective insulating film is exposed, and the transparent conductive layer is provided between the first protective insulating film which is located above the switching elements and the second protective insulating film along the groove of the second protective insulating film to be exposed from the sidewall of the groove while being recessed from the sidewall of the groove, and in other words, the second protective insulating film on the transparent conductive layer is disposed to cover the transparent conductive layer by forming overhangs. Therefore, even if a transparent conductive film for forming the pixel electrodes is left in the groove of the second protective insulating film, the transparent conductive film tears along the groove of the second protective insulating film due to a space formed by the transparent conductive layer. With the interruption, it becomes difficult to conduct adjoining ones of the pixel electrodes on the second protective insulating film to each other through the transparent conductive film located in the groove of the second protective insulating film, and therefore, it is possible to reliably reduce or prevent a short circuit between the adjoining ones of the pixel electrodes.

The transparent conductive layer may overlap the plurality of pixel electrodes through the second protective insulating film, thereby constituting an auxiliary capacitor.

According to the above configuration, the transparent conductive layer continuously provided across all of the pixels overlaps each of the plurality of pixel electrodes through the second protective insulating film, thereby constituting an auxiliary capacitor, and therefore, an advantage of the present invention is specifically achieved in the active matrix substrate in which the auxiliary capacitor is provided for each pixel.

The transparent conductive layer may include a plurality of transparent conductive layers each independently provided for a corresponding one of the plurality of pixels, and each overlapping a corresponding one of the plurality of pixel electrodes through the second protective insulating film, thereby constituting an auxiliary capacitor.

According to the above configuration, each of the plurality of the transparent conductive layers which is independently provided for the corresponding one of the plurality of pixels may overlap the corresponding one of the plurality of pixel electrodes through the second protective insulating film, thereby constituting the auxiliary capacitor, and therefore, the advantage of the present invention is specifically achieved in the active matrix substrate in which the auxiliary capacitor is provided for each pixel.

The transparent conductive layer may include a plurality of transparent conductive layers each provided for a corresponding one of the plurality of pixels in a frame shape, a transparent electrode may be provided within each of the transparent conductive layers between the first protective insulating film and the second protective insulating film, and the transparent electrode may overlap a corresponding one of the plurality of pixel electrodes through the second protective insulating film, thereby constituting an auxiliary capacitor.

According to the above configuration, the plurality of the transparent conductive layers each provided for the corresponding one of the plurality of pixels in a frame shape, and the transparent electrode provided within each of the transparent conductive layers between the first protective insulating film and the second protective insulating film overlaps each of the plurality of pixel electrodes through the second protective insulating film, thereby constituting an auxiliary capacitor. Therefore, the advantage of the present invention is specifically achieved in the active matrix substrate in which the auxiliary capacitor is provided for each pixel.

The transparent conductive layer may be thicker than each of the plurality of pixel electrodes.

According to the above configuration, the transparent conductive layer is formed to be thicker than each of the plurality of pixel electrodes, whereby a space formed by the transparent conductive layer has a higher height, and therefore, the transparent conductive film in the groove of the second protective insulating film can still reliably tear along the groove, and for example, the etchant used for the etching of the transparent conductive film can easily enter the bottom portion of the groove of the second protective insulating film.

A method for fabricating an active matrix substrate according to the present invention, the active matrix substrate including a plurality of pixels arranged in an matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in an matrix pattern on the second protective insulating film, and each connected to a corresponding one of the plurality of switching elements, includes a switching element formation step of forming the plurality of switching elements on a substrate, a first protective insulating film formation step of forming the first protective insulating film on the plurality of switching elements which have been formed, a transparent conduction formation layer formation step of forming a first transparent conductive film to cover the first protective insulating film which have been formed, and then, patterning the first transparent conductive film, thereby forming a transparent conduction formation layer serving as the transparent conductive layer, a second protective insulating film formation step of forming an insulating film to cover the transparent conduction formation layer, and then, forming a groove along a vicinity of regions each in which each of the plurality of pixel electrodes in the insulating film is disposed, thereby forming the second protective insulating film so that part of the transparent conduction formation layer is exposed, a transparent conductive layer formation step of etching the part of the transparent conduction formation layer exposed from the second protective insulating film which has been formed to allow the transparent conduction formation layer to move back from a sidewall of the groove of the second protective insulating film, thereby forming the transparent conductive layer, and a pixel electrode formation step of forming a second transparent conductive film on the second protective insulating film on the transparent conductive layer which has been formed, and then, patterning the second transparent conductive film, thereby forming the plurality of pixel electrodes.

According to the above method, in the first protective insulating film formation step, the first protective insulating film is formed on the plurality of switching elements which have been formed on the substrate in the switching element formation step, in the transparent conduction formation layer formation step, the first transparent conductive film is formed to cover the first protective insulating film, and then, the first transparent conductive film is patterned, thereby forming the transparent conduction formation layer, in the second protective insulating film formation step, the insulating film is formed to cover the transparent conduction formation layer, and then, the groove is formed in the insulating film along the vicinity of regions each in which each of the plurality of pixel electrodes is disposed, thereby forming the second protective insulating film so that the part of the transparent conduction formation layer is exposed, in the transparent conductive layer formation step, the part of the transparent conduction formation layer exposed from the second protective insulating film is etched to allow the transparent conduction formation layer to move back from the sidewall of the groove of the second protective insulating film, thereby forming the transparent conductive layer, and in the pixel electrode formation step, the second transparent conductive film is formed on the second protective insulating film on the transparent conductive layer, and then, the second transparent conductive film is patterned, thereby forming the plurality of pixel electrodes. Therefore, the second protective insulating film formed in the second protective insulating film formation step is disposed to cover the transparent conductive layer formed in the transparent conductive layer formation step by forming overhangs. Therefore, in the pixel electrode formation step, even if the second transparent conductive film is left in the groove of the second protective insulating film, the second transparent conductive film tears along the groove of the second protective insulating film due to a space formed by the transparent conductive layer. With the interruption, it becomes difficult to conduct adjoining ones of the pixel electrodes on the second protective insulating film to each other through the second transparent conductive film located in the groove of the second protective insulating film, and therefore, it is possible to reliably reduce or prevent a short circuit between the adjoining ones of the pixel electrodes.

A method for fabricating an active matrix substrate according to the present invention, the active matrix substrate including a plurality of pixels arranged in an matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in an matrix pattern on the second protective insulating film, and each connected to a corresponding one of the plurality of switching elements, includes a switching element formation step of forming the plurality of switching elements on a substrate, a first protective insulating film formation step of forming the first protective insulating film on the plurality of switching elements which have been formed, a transparent conduction formation layer formation step of forming a first transparent conductive film to cover the first protective insulating film which have been formed, and then, patterning the first transparent conductive film, thereby forming a transparent conduction formation layer serving as the transparent conductive layer, a second protective insulating film formation step of forming an insulating film to cover the transparent conduction formation layer, and then, forming a groove along a vicinity of regions each in which each of the plurality of pixel electrodes in the insulating film is disposed, thereby forming the second protective insulating film so that part of the transparent conduction formation layer is exposed, a pixel electrode formation step of forming a second transparent conductive film on the second protective insulating film which has been formed, and then, etching the part of the transparent conduction formation layer exposed from the second protective insulating film when patterning the second transparent conductive film to allow the transparent conduction formation layer to move back from a sidewall of the groove of the second protective insulating film, thereby forming the plurality of pixel electrodes and the transparent conductive film.

According to the above method, in the first protective insulating film formation step, the first protective insulating film is formed on the plurality of switching elements which have been formed on the substrate in the switching element formation step, in the transparent conduction formation layer formation step, the first transparent conductive film is formed to cover the first protective insulating film, and then, the first transparent conductive film is patterned, thereby forming the transparent conduction formation layer, in the second protective insulating film formation step, the insulating film is formed to cover the transparent conduction formation layer, and then, the groove is formed in the insulating film along the vicinity of regions each in which each of the plurality of pixel electrodes is disposed, thereby forming the second protective insulating film so that the part of the transparent conduction formation layer is exposed, and in the pixel electrode formation step, the second transparent conductive film is formed on the second protective insulating film, and then, the part of the transparent conduction formation layer exposed from the second protective insulating film is etched when patterning the second transparent conductive film to allow the transparent conduction formation layer to move back from the sidewall of the groove of the second protective insulating film, thereby forming the plurality of pixel electrodes and the transparent conductive layer. Therefore, the second protective insulating film formed in the second protective insulating film formation step is disposed to cover the transparent conductive layer formed in the pixel electrode formation step by forming overhangs. In the pixel electrode formation step, the second transparent conductive film is etched, and the transparent conduction formation layer exposed from the second protective insulating film is etched to allow the transparent conduction formation layer to move back from the sidewall of the groove of the second protective insulating film, whereby, e.g., the etchant used for the etching can easily enter the bottom portion of the groove of the second protective insulating film, and therefore, it becomes difficult to leave the second transparent conductive film located in the groove of the second protective insulating film. This makes it difficult to conduct adjoining ones of the pixel electrodes on the second protective insulating film to each other through the second transparent conductive film located in the groove of the second protective insulating film, and therefore, it is possible to reliably reduce or prevent a short circuit between the adjoining ones of the pixel electrodes.

In the pixel electrode formation step, the second transparent conductive film located in the groove of the second protective insulating film may be removed.

According to the above method, even if the second transparent conductive film in the groove of the second protective insulating film does not sufficiently tear, the second transparent conductive film located in the groove of the second protective insulating film is removed in the pixel electrode formation step, and therefore, it is possible to still reliably reduce or prevent a short circuit between the adjoining ones of the pixel electrodes.

The first transparent conductive film may be thicker than the second transparent conductive film.

According to the above method, the first transparent conductive film for forming the transparent conductive layer is formed to be thicker than the second transparent conductive film, whereby a space formed by the transparent conductive layer has a higher height, and therefore, the transparent conductive film in the groove of the second protective insulating film still reliably tears along the groove, and for example, the etchant used for the etching of the second transparent conductive film easily enter the bottom portion of the groove of the second protective insulating film.

The first transparent conductive film and the second transparent conductive film may be made of a compound of indium oxide and tin oxide, and the transparent conduction formation layer and the second transparent conductive film may have crystallinity.

According to the above method, since the first transparent conductive film and the second transparent conductive film are made of the compound of indium oxide and tin oxide, in other words, indium tin oxide (ITO), and the transparent conduction formation layer and the second transparent conductive film have crystallinity, the etching of the transparent conduction formation layer and the etching of the second transparent conductive film can be performed using the same etchant in the pixel electrode formation step, and therefore, the fabrication steps can be reduced.

The first transparent conductive film and the second transparent conductive film may be made of a compound of indium oxide and zinc oxide.

According to the above method, since the first transparent conductive film and the second transparent conductive film are made of the compound of indium oxide and zinc oxide, in other words, indium zinc oxide (IZO), the etching of the transparent conduction formation layer and the etching of the second transparent conductive film can be performed using the same etchant in the pixel electrode (formation) step, and therefore, the fabrication steps can be reduced.

A liquid crystal display panel according to the present invention includes an active matrix substrate and a counter substrate provided to face each other, and a liquid crystal layer provided between the active matrix substrate and the counter substrate, wherein the active matrix substrate includes a plurality of pixels arranged in an matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in an matrix pattern on the second protective insulating film, and each connected to a corresponding one of the plurality of switching elements, a groove is formed in the second protective insulating film along a vicinity of a corresponding one of the plurality of pixel electrodes so that part of the first protective insulating film is exposed, and the transparent conductive layer is provided along the groove of exposed the second protective insulating film to be exposed from a sidewall of the groove while being recessed from the sidewall of the groove.

According to the above configuration, in the active matrix substrate, the groove is formed in the second protective insulating film located under the pixel electrodes along the vicinity of each of the pixel electrodes, and the transparent conductive layer is provided between the first protective insulating film which is located above the switching elements and the second protective insulating film along the groove of the second protective insulating film to be exposed from a sidewall of the groove while being recessed from the sidewall of the groove, and in other words, the second protective insulating film on the transparent conductive layer is disposed to cover the transparent conductive layer by forming overhangs. Therefore, even if a transparent conductive film for forming the pixel electrodes is left in the groove of the second protective insulating film, the transparent conductive film tears along the groove of the second protective insulating film due to a space formed by the transparent conductive layer. With the interruption, in the active matrix substrate, it becomes difficult to conduct adjoining ones of the pixel electrodes on the second protective insulating film to each other through the transparent conductive film located in the groove of the second protective insulating film, and therefore, it is possible to reliably reduce or prevent a short circuit between the adjoining ones of the pixel electrodes.

### Advantages of the Invention

According to the present invention, the transparent conductive layer is provided between the first protective insulating film located above the respective switching elements and the second protective insulating film located under the respective pixel electrodes along the groove of the second protective insulating film to be exposed from the sidewall of the groove while being recessed from the sidewall of the groove, and therefore, it is possible to reliably reduce or prevent a short circuit between the adjoining ones of the pixel electrodes.

### BRIEF DESCRIPTION OF THE DRAWINGS

FIG. 1 is a cross-sectional view of a liquid crystal display panel including an active matrix substrate according to a first embodiment.

FIG. 2 is a plan view of the active matrix substrate according to the first embodiment.

FIG. 3 is an enlarged view of a region X of FIG. 2.

FIG. 4 is a cross-sectional view of the active matrix substrate taken along the line IV-IV of FIG. 2.

FIG. 5 is a cross-sectional view of the active matrix substrate taken along the line V-V of FIG. 2.

FIG. 6 is a cross-sectional view of the active matrix substrate taken along the line VI-VI of FIG. 2.

FIG. 7 is a cross-sectional view of the active matrix substrate taken along the line VII-VII of FIG. 2.

FIG. 8 shows first cross-sectional views illustrating steps for fabricating the active matrix substrate according to the first embodiment.

FIG. 9 shows second cross-sectional views illustrating steps for fabricating the active matrix substrate according to the first embodiment, following the steps of FIG. 8.

FIG. 10 shows third cross-sectional views illustrating steps for fabricating the active matrix substrate according to the first embodiment, following the steps of FIG. 9.

FIG. 11 shows fourth cross-sectional views illustrating steps for fabricating the active matrix substrate according to the first embodiment, following the steps of FIG. 10.

FIG. 12 shows first cross-sectional views illustrating steps for fabricating an active matrix substrate according to a second embodiment.

FIG. 13 shows second cross-sectional views illustrating steps for fabricating the active matrix substrate according to the second embodiment, following the steps of FIG. 12.

FIG. 14 shows third cross-sectional views illustrating steps for fabricating the active matrix substrate according to the second embodiment, following the steps of FIG. 13.

FIG. 15 shows cross-sectional views illustrating steps for fabricating an active matrix substrate according to a third embodiment.

FIG. 16 is a plan view of an active matrix substrate according to a fourth embodiment.

FIG. 17 is a cross-sectional view of the active matrix substrate taken along the line XVII-XVII of FIG. 16.

FIG. 18 is a cross-sectional view of the active matrix substrate taken along the line XVIII-XVIII of FIG. 16.

FIG. 19 is a plan view of an active matrix substrate according to a fifth embodiment.

FIG. 20 is a cross-sectional view of the active matrix substrate taken along the line XX-XX of FIG. 19.

FIG. 21 is a cross-sectional view of the active matrix substrate taken along the line XXI-XXI of FIG. 19.

FIG. 22 is a cross-sectional view of the active matrix substrate taken along the line XXII-XXII of FIG. 19.

### DESCRIPTION OF EMBODIMENTS

Embodiments of the present invention will be described in detail hereinafter with reference to the drawings. The present invention is not limited to the following embodiments.

### First Embodiment of the Invention

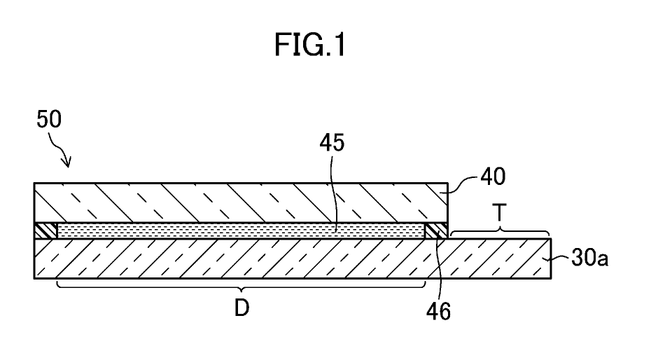

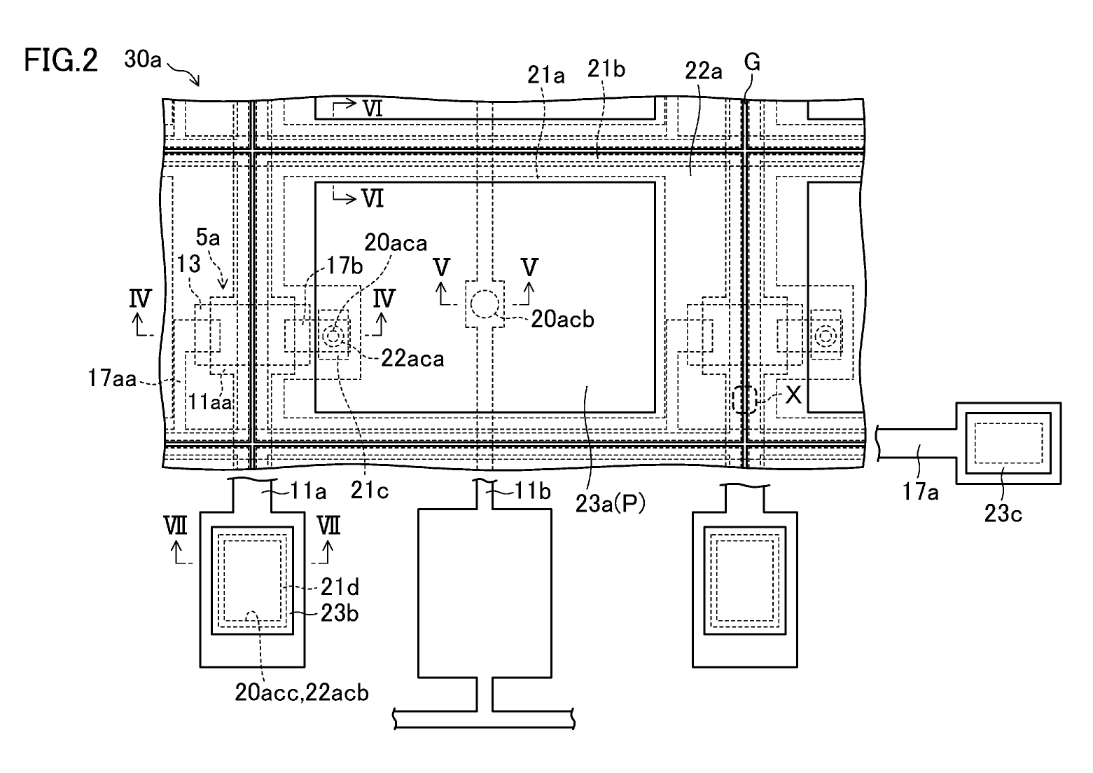

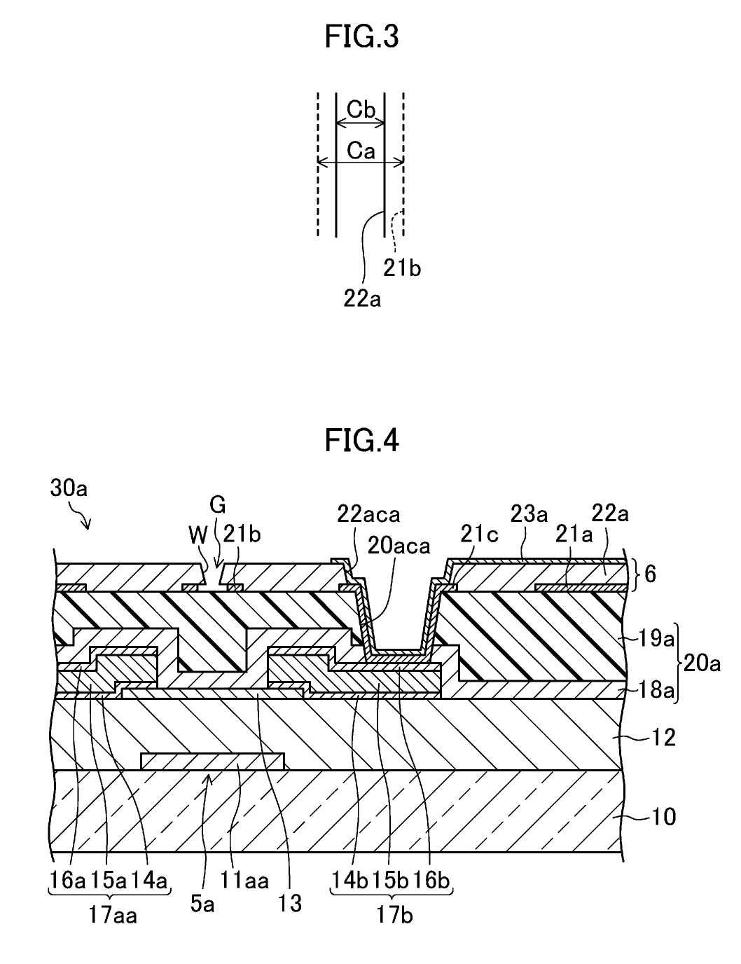

FIGS. 1-11 illustrate a first embodiment of an active matrix substrate, a method for fabricating the same, and a liquid crystal display panel according to the present invention. Specifically, FIG. 1 is a cross-sectional view of a liquid crystal display panel 50 including an active matrix substrate 30a according to this embodiment. FIG. 2 is a plan view of the active matrix substrate 30a, and FIG. 3 is an enlarged view of a region X of FIG. 2. FIGS. 4, 5, 6, and 7 are cross-sectional views of the active matrix substrate 30a respectively taken along the line IV-IV, the line V-V, the line VI-VI, and the line VII-VII of FIG. 2.

The liquid crystal display panel 50 includes, as shown in FIG. 1, the active matrix substrate 30a and a counter substrate 40 provided to face each other, a liquid crystal layer 45 provided between the active matrix substrate 30a and the counter substrate 40, and a frame-shaped sealing material 46 provided to bond the active matrix substrate 30a and the counter substrate 40 together, and to enclose the liquid crystal layer 45 between the active matrix substrate 30a and the counter substrate 40. In the liquid crystal display panel 50, as shown in FIG. 1, a display region D is defined for displaying an image within the sealing material 46, and a terminal region T is defined on the surface of the active matrix substrate 30a exposed from the counter substrate 40. In the display region D, a plurality of pixels P (see FIG. 2) each constituting the smallest unit of an image are arranged in a matrix pattern.

The active matrix substrate 30a includes, as shown in FIG. 2, an insulating substrate 10, a plurality of gate lines 11a provided on the insulating substrate 10 to extend in parallel to each other, a plurality of capacitor lines 11b each provided between two of the gate lines 11a to extend in parallel to each other, a plurality of source lines 17a provided to extend in parallel to each other along a direction perpendicular to the gate lines 11a, a plurality of TFTs 5a, as a switching element, each provided at an interconnection portion between the gate line 11a and the source line 17a (one TFT 5a is provided for each pixel P), a first protective insulating film 20a (see FIGS. 4-7) provided on the TFTs 5a, a second protective insulating film 22a formed on the first protective insulating film 20a, a plurality of pixel electrodes 23a arranged in an matrix pattern on the second protective insulating film 22a, and an alignment film (not shown) provided to cover the pixel electrodes 23a.

Each of the TFTs 5a includes, as shown in FIGS. 2 and 4, a gate electrode 11aa provided on the insulating substrate 10, a gate insulating film 12 provided to cover the gate electrode llaa, a semiconductor layer 13 provided on the gate insulating film 12 to overlap the gate electrode 11aa, and a source electrode 17aa and the drain electrode 17b which are provided on the semiconductor layer 13 to be spaced from each other.

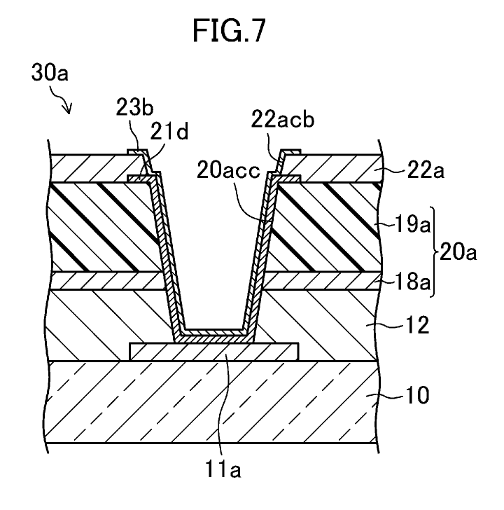

As shown in FIG. 2, the gate electrode 11aa is a wider portion of each of the gate lines 11a. As shown in FIGS. 2 and 7, the gate line 11a is extended to the terminal region T, and is connected to a gate terminal 23b in the terminal region T through a contact hole 20acc formed in the gate insulating film 12 and a first protective insulating film 20a, a transparent conductive layer 21d formed in the contact hole 20acc, and a contact hole 22acb formed in the second protective insulating film 22a.

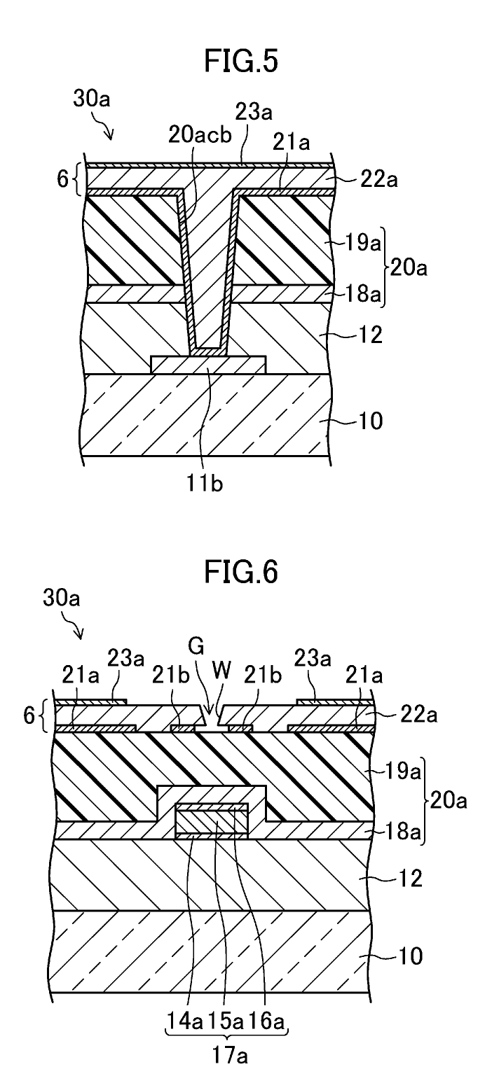

As shown in FIG. 2, the source electrode 17aa is a laterally protruding, L-shaped part of the source line 17a. Each of the source electrode 17aa and the source line 17a has, as shown in FIGS. 4 and 6, a multilayer structure in which a first metal layer 14a, a second metal layer 15a, and a third metal layer 16a are sequentially stacked. As shown in FIG. 2, the source lines 17a is extended to the terminal region T, and is connected to a source terminal 23c in the terminal region T through the contact hole (the broken line) formed in the first protective insulating film 20a and the second protective insulating film 22a.

As shown in FIGS. 2 and 4, the drain electrode 17b is connected to the pixel electrode 23a through a contact hole 20aca formed in the first protective insulating film 20a, a transparent conductive layer 21c formed in the contact hole 20aca, and a contact hole 22aca formed in the second protective insulating film 22a. The drain electrode 17b has, as shown in FIG. 4, a multilayer structure in which a first metal layer 14b, a second metal layer 15b, a third metal layer 16b are sequentially stacked.

The first protective insulating film 20a has, as shown in FIGS. 4-7, a multilayer structure in which a lower protective insulating film 18a and an upper protective insulating film 19a are sequentially stacked.

As shown in FIGS. 2, 4, and 6, in the second protective insulating film 22a, a groove G is formed in a grid pattern along the vicinity of each of the pixel electrodes 23a so that the first protective insulating film 20a is exposed.

As shown in FIG. 2, a frame-shaped transparent conductive layer 21b is provided for each pixel P between the first protective insulating film 20a and the second protective insulating film 22a, and within the frame, a transparent electrode 21a is provided to overlap each of the pixel electrodes 23a, and the transparent conductive layer 21c is provided to overlap the contact hole 20aca of the first protective insulating film 20a, and the contact hole 22aca of the second protective insulating film 22a.

As shown in FIGS. 4 and 6, the transparent conductive layer 21b is provided along the groove G of the second protective insulating film 22a to be exposed from a sidewall W of the groove G while being recessed from the sidewall W of the groove G. In adjoining ones of the pixels P, as shown in FIG. 3, an interval Ca between adjoining ones of the transparent conductive layer 21b (for example, 3.2 μm-22.2 μm) is wider than a width Cb of the groove G of the second protective insulating film 22a (for example, 3 μm-22 μm) by approximately 0.2 μm or more.

The transparent electrode 21a is, as shown in FIGS. 2, and 4-6, connected to the capacitor line 11b through a contact hole 20acb formed in the gate insulating film 12 and the first protective insulating film 20a, and overlaps each of the pixel electrodes 23a through the second protective insulating film 22a, thereby constituting an auxiliary capacitor 6.

The counter substrate 40 includes an insulating substrate (not shown) made of, e.g., a glass substrate, a black matrix (not shown) provided on the insulating substrate in a grid pattern, and color filters (not shown) each in which a red layer, a green layer, and a blue layer, etc., are provided between grid lines of the black matrix, and a common electrode (not shown) provided to cover the black matrix and the color filters, and an alignment film (not shown) provided to cover the common electrode.

The liquid crystal layer 45 is made of, for example, a nematic liquid crystal material having an electrooptical properties etc.

In the liquid crystal display panel 50 having the above configuration, when the TFT 5a is turned on in each pixel P in response to a scan signal from the gate line 11a, a predetermined charge is written to the pixel electrodes 23a in response to a display signal from the source line 17a, whereby a potential difference occurs between each of the pixel electrodes 23a on the active matrix substrate 30a and a common electrode on the counter substrate 40, and a predetermined voltage is applied to a liquid crystal layer 45 (i.e., a liquid crystal capacitor of each pixel P) and the auxiliary capacitor 6 connected in parallel to the liquid crystal capacitor. In the liquid crystal display panel 50, the alignment of the liquid crystal layer 45 is changed, depending on the magnitude of the voltage applied to the liquid crystal layer 45, to adjust the transmittance of the light transmitting the panel in each pixel P, thereby displaying an image.

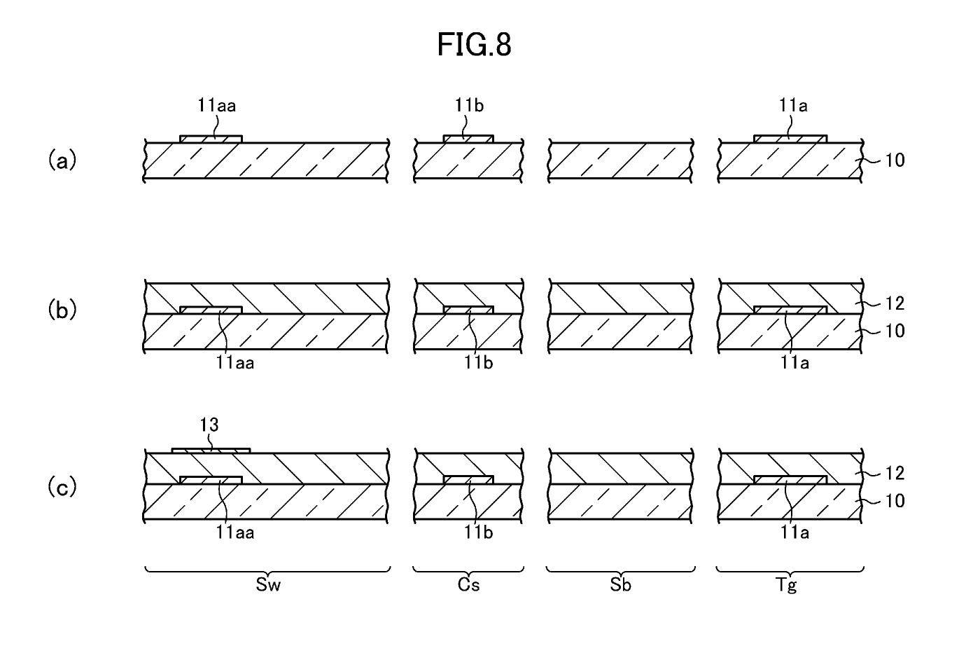

Next, a method for fabricating active matrix substrate 30a in this embodiment will be described with reference to FIGS. 8-11. FIGS. 8-11, corresponding to respective portions of the active matrix substrate 30a in the cross-sectional views of FIGS. 4-7, are cross-sectional views continuously illustrating steps for fabricating the active matrix substrate 30a in this embodiment. Specifically, a region Sw, a region Cs, a region Sb, and a region Tg in a lower side of each of FIGS. 8-11 respectively correspond to the cross-sectional views of FIGS. 4, 5, 6, and 7. The fabrication method of this embodiment includes a TFT (switching element) formation step, a first protective insulating film formation step, a transparent conduction formation layer formation step, a second protective insulating film formation step, a transparent conductive layer formation step, and a pixel electrode fabricating step.

### <TFT Formation Step>

Initially, an aluminum film (thickness: approximately 50 nm-350 nm), a titanium film (thickness: approximately 50 nm-200 nm), and a titanium nitride film (thickness: approximately 5 nm-20 nm) are sequentially formed by, e.g., a sputtering method on the entire insulating substrate 10, such as a glass substrate etc., to form a metal multilayer film and thereafter, the metal multilayer film is subjected to photolithography, wet etching or dry etching, resist removal, and cleaning, thereby forming the gate line 11a, the gate electrode 11aa, and the capacitor line 11b, as shown in FIG. 8(a).

Subsequently, an inorganic insulating film (thickness: approximately 200 nm to 500 nm), such as an silicon oxide film, a silicon nitride film, etc., is formed by, e.g., a CVD (Chemical Vapor Deposition) method on the entire substrate on which the gate line 11a, the gate electrode 1aa, and the capacitor line 11b have been formed, thereby forming the gate insulating film 12, as shown in FIG. 8(b).

Moreover, an In—Ga—Zn—O-based oxide semiconductor film (thickness: approximately 20 nm to 200 nm) is formed by, e.g., a sputtering method on the entire substrate on which the gate insulating film 12 has been formed, and thereafter, the oxide semiconductor film is subjected to photolithography, wet etching, resist removal, and cleaning, thereby forming the semiconductor layer 13, as shown in FIG. 8(c).

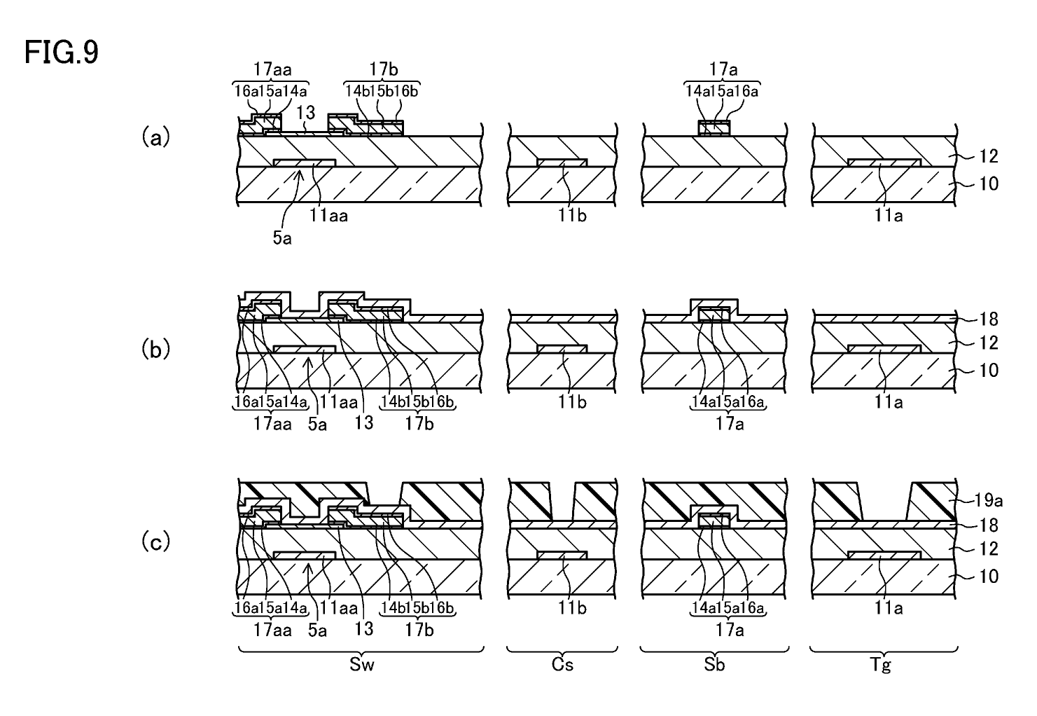

Subsequently, a molybdenum nitride film (thickness: approximately 20 nm-100 nm) serving as the first metal layers 14a and 14b, an aluminum film (thickness: approximately 50 nm-350 nm) serving as the second metal layers 15a and 15b, and a molybdenum nitride film (thickness: approximately 50 nm-200 nm) serving as the third metal layers 16a and 16b are sequentially formed by, e.g., a sputtering method on the entire substrate on which the oxide semiconductor layer 13 has been formed to form a metal multilayer film, and thereafter, the metal multilayer film is subjected to photolithography, wet etching or dry etching, resist removal, and cleaning, thereby forming the source line 17a, the source electrode 17aa, and the drain electrode 17b to form the TFT 5a, as shown in FIG. 9(a). In this embodiment, the molybdenum nitride films have been illustrated as an upper refractory metal film and a lower refractory metal film constituting the metal multilayer film. The refractory metal films may be a titanium film, a tungsten film, or an alloy film of them.

### <First Protective Insulating Film Formation Step>

Initially, as shown in FIG. 9(b), an inorganic insulating film (thickness: approximately 50 nm-500 nm) 18, such as a silicon oxide film, a silicon nitride film, etc., is formed by, e.g., a CVD method on the substrate on which the TFT 5a has been formed in the TFT formation step.

Subsequently, a transparent photosensitive resin film (thickness: approximately 1 μm-4 μm) is coated by, e.g., a spin coating method or a slit coating method on the entire substrate on which the inorganic insulating film 18 has been formed, and thereafter, the transparent photosensitive resin film is exposed, developed, and baked, thereby forming the upper protective insulating film 19a, as shown in FIG. 9(c).

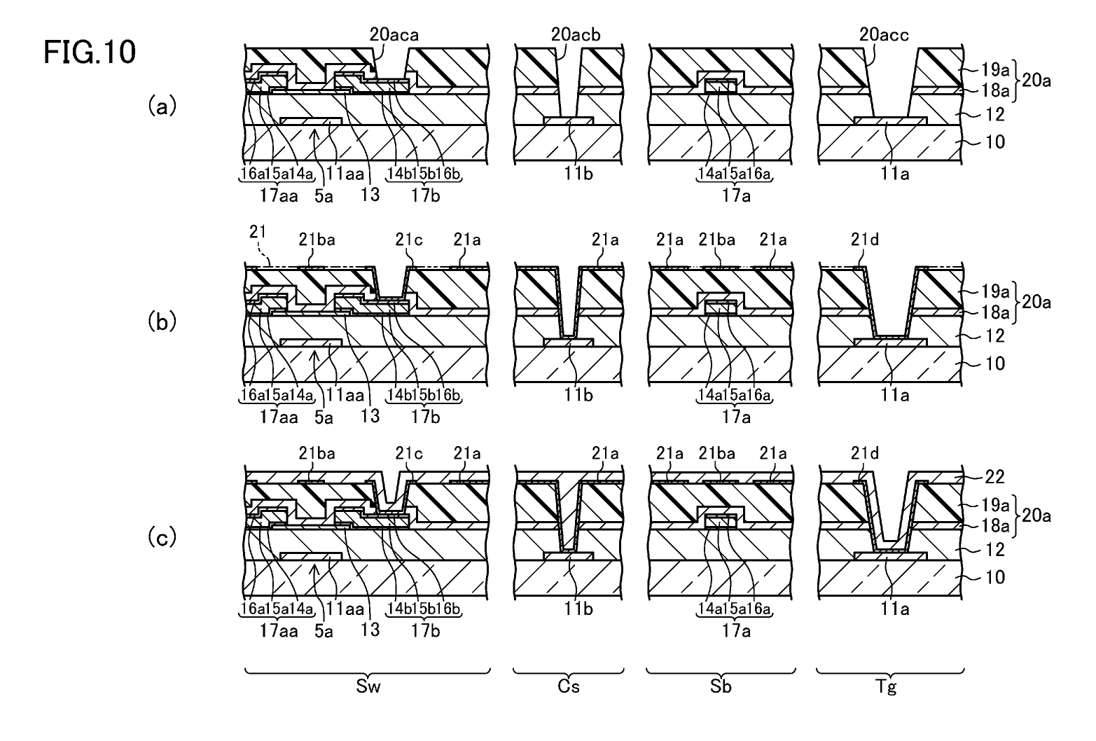

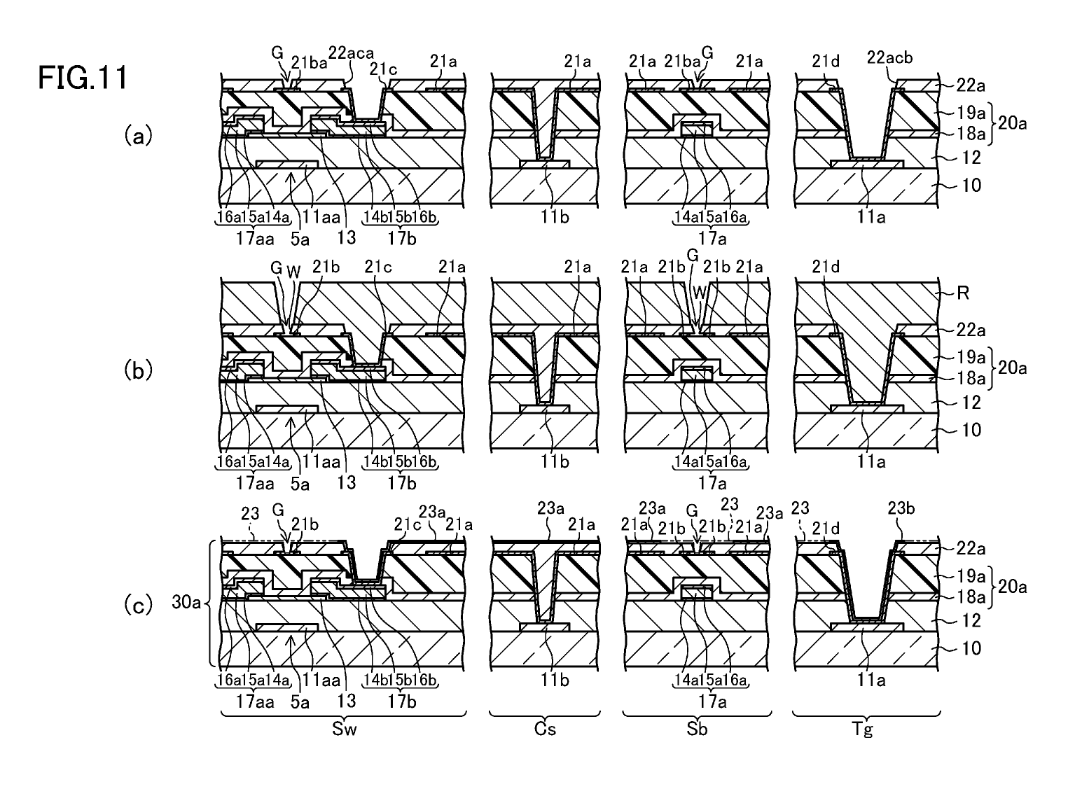

Moreover, as shown in FIG. 10(a), the inorganic insulating film 18 exposed from the upper protective insulating film 19a is subjected to wet etching or dry etching, thereby forming the contact holes 20aca, 20acb, and 20acc to form the first protective insulating film 20a including the lower protective insulating film 18a and the upper protective insulating film 19a.

<Transparent Conduction Formation Layer Formation Step>

A first transparent conductive film (thickness: approximately 50 nm-300 nm) 21, such as an ITO film etc., is formed by, e.g., a sputtering method on the entire substrate on which the first protective insulating film 20a formed in the first protective insulating film formation step has been formed, and thereafter, the first transparent conductive film 21 is subjected to photolithography, wet etching or dry etching, resist removal, and cleaning, thereby forming the transparent electrode 21a, transparent conduction formation layer 21ba, and the transparent conductive layers 21c and 21d, as shown in FIG. 10(b).

<Second Protective Insulating Film Formation Step>

As shown in FIG. 10(c), an inorganic insulating film (thickness: approximately 50 nm-500 nm) 22, such as a silicon oxide film, a silicon nitride film, etc., is formed by, e.g., a CVD method on the substrate on which the transparent electrode 21a, the transparent conduction formation layer 21ba, and the transparent conductive layers 21c and 21d have been formed in the transparent conduction formation layer formation step, and thereafter, the inorganic insulating film 22 is subjected to photolithography, wet etching or dry etching, resist removal, and cleaning, thereby forming the contact holes 22aca and 22acb, and the groove G in a grid pattern along the vicinity of regions each in which the pixel electrode 23a is formed so that part of the transparent conduction formation layer 21ba is exposed, thereby forming the second protective insulating film 22a, as shown in FIG. 11(a).

<Transparent Conductive Layer Formation Step>

A photosensitive resin film (thickness: approximately 1 μm-4 μm) is coated by, e.g., a spin coating method or a slit coating method on the entire substrate on which the second protective insulating film 22a formed in the second protective insulating film formation step has been formed, and thereafter, the photosensitive resin film is exposed, developed, and baked, thereby forming a resist R, and the transparent conduction formation layer 21ba exposed from the resist R is subjected to wet etching, thereby allowing the transparent conduction formation layer 21ba to move back from the sidewall W of the groove G of the second protective insulating film 22a to form the portion of the transparent conductive layer 21b, as shown in FIG. 11(b).

<Pixel Electrode Formation Step>

A second transparent conductive film (thickness: approximately 30 nm-150 nm) 23, such as an ITO film etc., is formed by, e.g., a sputtering method on the entire substrate on which the resist R used in the transparent conductive layer formation step have been removed and cleaned, and thereafter, the second transparent conductive film 23 is subjected to photolithography, wet etching, resist removal, and cleaning, thereby forming the pixel electrode 23a, the gate terminal 23b, and the source terminal 23c (see FIG. 2), as shown in FIG. 11(c).

In this way, the active matrix substrate 30a of this embodiment can be fabricated.

As described above, according to the active matrix substrate 30a, and the method for fabricating the same, and the liquid crystal display panel 50 in this embodiment, in the first protective insulating film formation step, the first protective insulating film 20a is formed on the respective TFT 5a which has been formed on the insulating substrate 10 in the TFT formation step, in the transparent conduction formation layer formation step, the first transparent conductive film 21 is formed to cover the first protective insulating film 20a, and thereafter, the first transparent conductive film 21 is patterned to form the transparent conduction formation layer 21ba, in the second protective insulating film formation step, the inorganic insulating film 22 is formed to cover the transparent conduction formation layers 21ba, and thereafter, the groove G is formed along the vicinity of the regions each in which the pixel electrode 23a in the inorganic insulating film 22 is disposed, thereby forming the second protective insulating film 22a to expose part of the transparent conduction formation layer 21ba, in the transparent conductive layer formation step, the transparent conduction formation layer 21ba exposed from the second protective insulating film 22a is etched, thereby allowing the transparent conduction formation layer 21ba to move back from the sidewall W of the groove G of the second protective insulating film 22a to form the transparent conductive layer 21b, in the pixel electrode formation step, the second transparent conductive film 23 is formed on the second protective insulating film 22a on the transparent conductive layer 21b, and thereafter, the second transparent conductive film 23 is patterned to form the pixel electrode 23a. Therefore, the second protective insulating film 22a formed in the second protective insulating film formation step is disposed to cover the portion of the transparent conductive layer 21b formed in the transparent conductive layer formation step by forming overhangs. Therefore, in the pixel electrode formation step, even if the second transparent conductive film 23 is left in the groove G of the second protective insulating film 22a, as shown in FIG. 11(c), the second transparent conductive film 23 can tear along the groove G of the second protective insulating film 22a due to a space formed by the transparent conductive layer 21b. With the interruption, in the active matrix substrate 30a, it becomes difficult to conduct adjoining ones of the pixel electrodes 23a on the second protective insulating film 22a to each other through the second transparent conductive film 23 in the groove G of the second protective insulating film 22a, and therefore, it is possible to reliably reduce or prevent a short circuit between the adjoining ones of the pixel electrodes 23a in the active matrix substrate 30a and the liquid crystal display panel 50 including the same.

According to the active matrix substrate 30a and the method for fabricating the same in this embodiment, even if the second transparent conductive film 23 in the groove G of the second protective insulating film 22a does not sufficiently tear, the second transparent conductive film 23 located in the groove G of the second protective insulating film 22a can be removed by wet etching in the pixel electrode formation step, and therefore, it is possible to be still reliably reduce or prevent a short circuit between the adjoining ones of the pixel electrodes 23a.

According to the active matrix substrate 30a and the method for fabricating the same in this embodiment, since the first transparent conductive film 21 for forming the portion of the transparent conductive layer 21b is thicker than the second transparent conductive film 23, and a space formed by the transparent conductive layer 21b has a higher height, the second transparent conductive film 23 in the groove G of the second protective insulating film 22a can still reliably tear along the groove G, and the etchant used for the etching of the second transparent conductive film 23 can easily enter the bottom portion of the groove G of the second protective insulating film 22a.

According to the active matrix substrate 30a in this embodiment, the semiconductor layer 13 is made of an oxide semiconductor, and therefore, the TFT 5 can have satisfactory characteristics, such as high mobility, high reliability, low off current, etc.

### Second Embodiment of the Invention

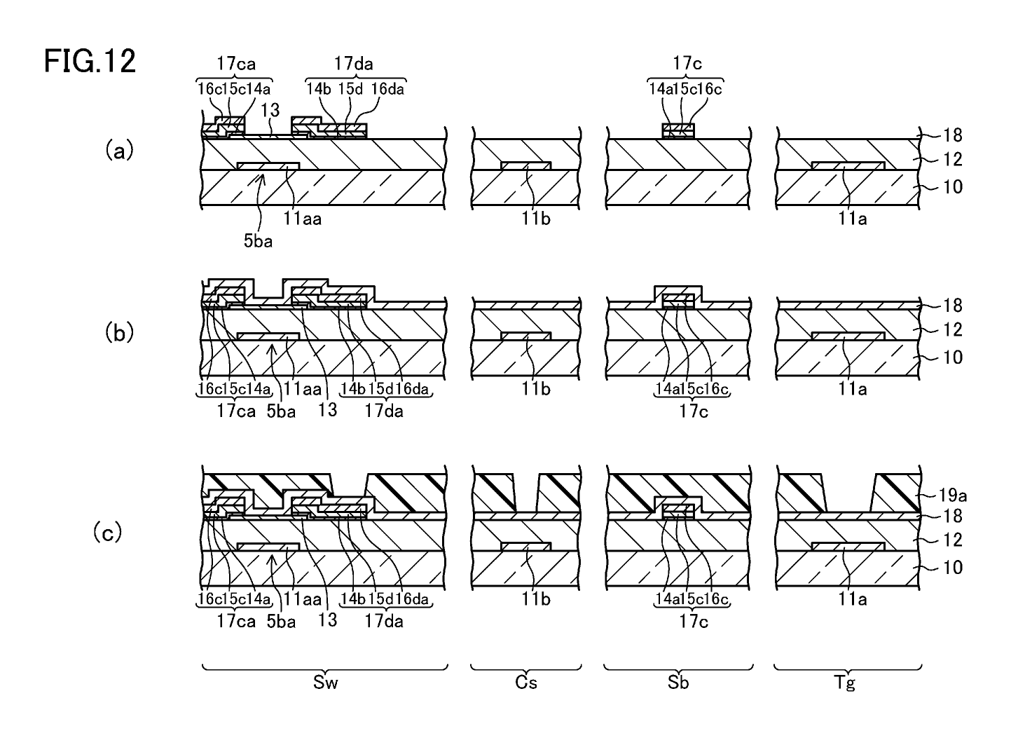

FIGS. 12-14 illustrate a second embodiment of the active matrix substrate, the method for fabricating the same, and the liquid crystal display panel according to the present invention. Specifically, FIGS. 12-14 are cross-sectional views continuously illustrating steps for fabricating an active matrix substrate 30b according to this embodiment. As well as the first embodiment, a region Sw, a region Cs, a region Sb, and a region Tg in a lower side of each of FIGS. 12-14 respectively corresponds to a partial cross-sectional view of a TFT, a partial cross-sectional view of a capacitor line, a partial cross-sectional view of a source line, and a partial cross-sectional view of a gate terminal. In the following embodiments, the same components as those shown in FIGS. 1-11 will be indicated by the same reference characters to omit detailed description thereof.

The above first embodiment has illustrated the method for fabricating the active matrix substrate 30a in which a third metal layer 16b for forming the drain electrode 17b is made relatively thinner, whereas this embodiment will illustrate a method for fabricating the active matrix substrate 30b in which a third metal layer 16da for forming a drain electrode 17d is made relatively thicker.

The liquid crystal display panel in this embodiment includes the active matrix substrate 30b and a counter substrate (40) provided to face each other, a liquid crystal layer (45) provided between the active matrix substrate 30b and the counter substrate (40), and a frame-shaped sealing material 46 provided to bond the active matrix substrate 30b and the counter substrate (40) together, and to enclose the liquid crystal layer (45) between the active matrix substrate 30b and the counter substrate (40).

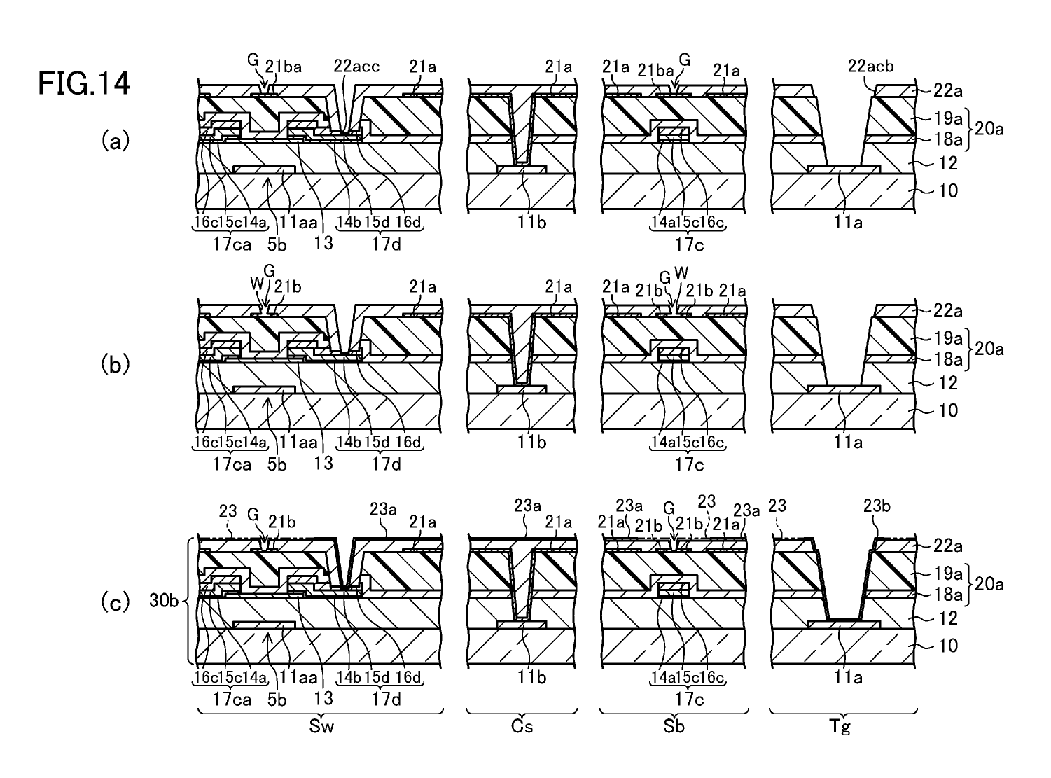

In the active matrix substrate 30b, as shown in FIG. 14(c), second metal layers 15c and 15d are made relatively thinner than the corresponding elements in the active matrix substrate 30a of the first embodiment, and third metal layers 16c and 16d are made relatively thicker than the corresponding elements in the active matrix substrate 30a of the first embodiment, and the transparent conductive layers 21c and 21d disposed between the first protective insulating film 20a and the second protective insulating film 22a are omitted. Other configurations are substantially the same as those in the active matrix substrate 30a in the first embodiment.

Next, the method for fabricating active matrix substrate 30b in this embodiment will be described with reference to FIGS. 12-14. The fabrication method of this embodiment includes a TFT formation step, a first protective insulating film formation step, a transparent conduction formation layer formation step, a second protective insulating film formation step, a transparent conductive layer formation step, and a pixel electrode formation step.

<TFT Formation Step>

As well as the first embodiment, a molybdenum nitride film (thickness: approximately 20 nm-100 nm) serving as first metal layers 14a and 14b, an aluminum film (thickness: approximately 50 nm-350 nm) serving as the second metal layers 15a and 15b, and a molybdenum nitride film (thickness: approximately 100 nm-300 nm) serving as the third metal layers 16a and 16b are sequentially formed on the entire substrate on which a gate line 11a, a gate electrode 11aa, a capacitor line 11b, a gate insulating film 12, a semiconductor layer 13 have been sequentially formed by, e.g., a sputtering method to form a metal multilayer film, and thereafter, the metal multilayer film is subjected to photolithography, wet etching or dry etching, resist removal, and cleaning, thereby forming a source line 17c, a source electrode 17ca, and a drain electrode formation portion 17da to form a TFT formation portion 5ba, as shown in FIG. 12(a).

<First Protective Insulating Film Formation Step>

Initially, as shown in FIG. 12(b), an inorganic insulating film (thickness: approximately 50 nm-500 nm) 18, such as a silicon oxide film, a silicon nitride film, etc., is formed by, e.g., a CVD method on the substrate on which the TFT formation portion 5ba formed in the TFT formation step has been formed.

Subsequently, a transparent photosensitive resin film (thickness: approximately 1 μm-4 μm) is coated by, e.g., a spin coating method or a slit coating method on the entire substrate on which the inorganic insulating film 18 has been formed, and thereafter, the transparent photosensitive resin film is exposed, developed, and baked, thereby forming an upper protective insulating film 19a, as shown in FIG. 12(c).

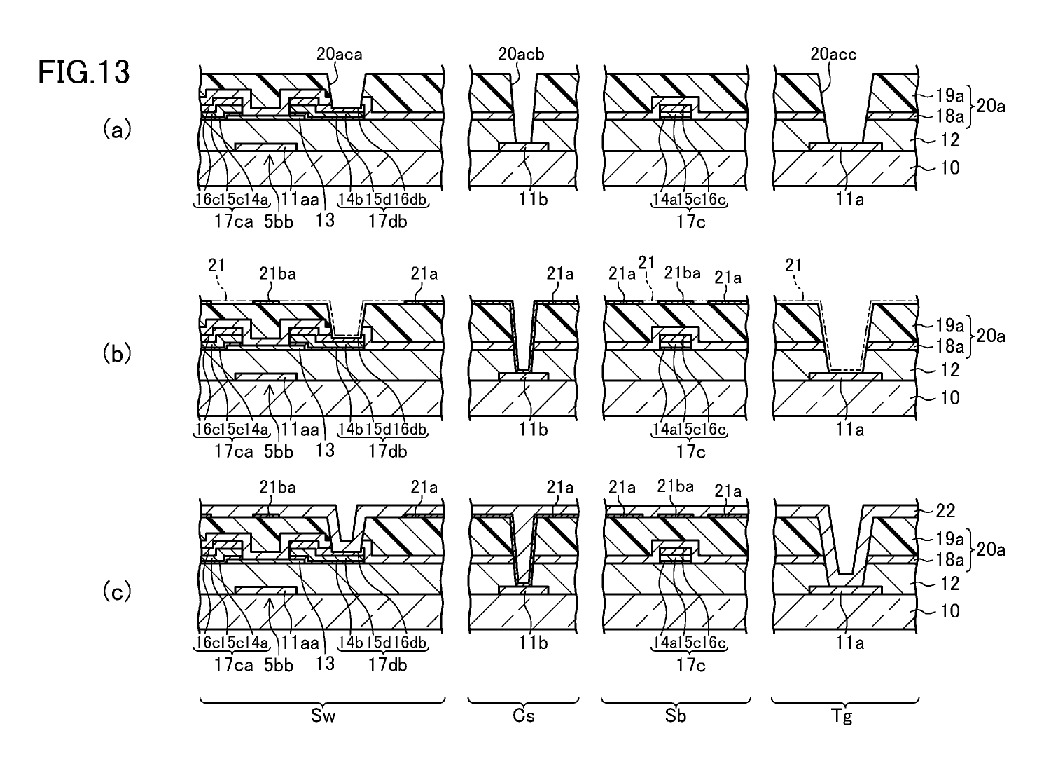

Moreover, as shown in FIG. 13(a), the inorganic insulating film 18 exposed from the upper protective insulating film 19a is subjected to wet etching or dry etching, thereby forming contact holes 20aca, 20acb, and 20acc to form the first protective insulating film 20a including a lower protective insulating film 18a and the upper protective insulating film 19a. At that time, the upper part of the third metal layer 16da of the drain electrode formation portion 17da is removed, thereby forming a third metal layer 16db, a drain electrode formation portion 17db, and a TFT formation portion 5bb.

<Transparent Conduction Formation Layer formation Step>

A first transparent conductive film (thickness: approximately 50 nm-300 nm) 21, such as an ITO film etc., is formed by, e.g., a sputtering method on the entire substrate on which the first protective insulating film 20a formed in the first protective insulating film formation step has been formed, and thereafter, the first transparent conductive film 21 is subjected to photolithography, wet etching or dry etching, resist removal, and cleaning, thereby forming the transparent electrode 21a, and a transparent conduction formation layer 21ba, as shown in FIG. 13(b).

<Second Protective Insulating Film Formation Step>

As shown in FIG. 13(c), an inorganic insulating film (thickness: approximately 50 nm-500 nm) 22, such as a silicon oxide film, a silicon nitride film, etc., is formed by, e.g., a CVD method on the substrate on which the transparent electrode 21a, and the transparent conduction formation layer 21ba formed in the transparent conduction formation layer formation step have been formed, and thereafter, the inorganic insulating film 22 is subjected to photolithography, wet etching or dry etching, resist removal, and cleaning, thereby forming contact holes 22aca and 22acb, and the groove G in a grid pattern along the vicinity of regions each in which a pixel electrode 23a is formed so that part of the transparent conduction formation layer 21ba is exposed, thereby forming the second protective insulating film 22a, as shown in FIG. 14(a). At that time, the upper part of the third metal layer 16db of the drain electrode formation portion 17db is removed, thereby forming the third metal layer 16db, the drain electrode 17d, and the TFT 5b.

<Transparent Conductive Layer formation Step>

The transparent conduction formation layer 21ba exposed from the second protective insulating film 22a formed in the second protective insulating film formation step is subjected to wet etching, thereby allowing the transparent conduction formation layer 21ba to move back from the sidewall W of the groove G of the second protective insulating film 22a to form a transparent conductive layer 21b, as shown in FIG. 14(b).

<Pixel Electrode Formation Step>

A second transparent conductive film (thickness: approximately 30 nm-150 nm) 23, such as an ITO film etc., is formed by, e.g., a sputtering method on the entire substrate on which the transparent conductive layer 21b has been formed in the transparent conductive layer formation step, and thereafter, the second transparent conductive film 23 is subjected to photolithography, wet etching, resist removal, and cleaning, thereby forming the pixel electrode 23a, the gate terminal 23b, and the source terminal (23c), as shown in FIG. 14(c).

In this way, the active matrix substrate 30b of this embodiment can be fabricated.

As described above, according to the active matrix substrate 30b, and the method for fabricating the same in this embodiment, as well as the first embodiment, the transparent conductive layer 21b disposed between the first protective insulating film 20a located above the TFTs 5b and the second protective insulating film 22a located under the pixel electrodes 23a is provided along the groove G of the second protective insulating film 22a to be exposed from the sidewall W of the groove G while being recessed from the sidewall W of the groove G. Therefore, it is possible to reliably reduce or prevent a short circuit between the adjoining ones of the pixel electrodes 23a.

According to the active matrix substrate 30b, and the method for fabricating the same in this embodiment, unlike the first embodiment, the transparent conductive layer 21c is not disposed in the contact hole 20aca of the first protective insulating film 20a, and therefore, it is unnecessary to form a resist R for forming the transparent conductive layer 21b, thereby making it possible to reduce fabrication steps and a fabrication cost.

### Third Embodiment of the Invention

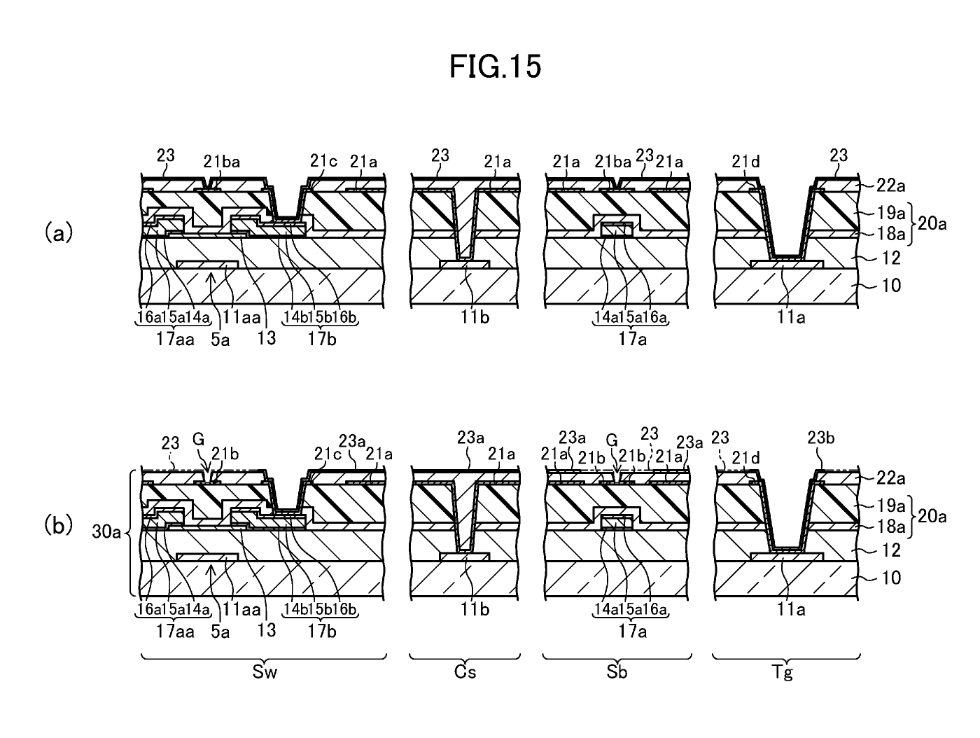

FIG. 15 shows cross-sectional views illustrating steps for fabricating an active matrix substrate 30a according to this embodiment.

The above embodiments have illustrated the methods for fabricating the active matrix substrates 30a and 30b each in which the transparent conductive layers 21b and the pixel electrodes 23a are patterned in different steps, whereas this embodiment will illustrate a method for fabricating the active matrix substrate 30a in which transparent conductive layers 21b and pixel electrodes 23a are patterned in the same step.

The method for fabricating active matrix substrate 30a in this embodiment will be described below with reference to FIG. 15. The fabrication method of this embodiment includes a TFT formation step, a first protective insulating film formation step, a transparent conduction formation layer formation step, a second protective insulating film formation step, and a pixel electrode formation step. The TFT formation step, the first protective insulating film formation step, and the transparent conduction formation layer formation step are substantially the same as those in the first embodiment to omit detailed description thereof.

<Second Protective Insulating Film Formation Step>

As shown in FIG. 10(c), an inorganic insulating film (thickness: approximately 50 nm-500 nm) 22, such as a silicon oxide film, a silicon nitride film, etc., is formed by, e.g., a CVD method on the substrate on which a transparent electrode 21a, a transparent conduction formation layer 21ba, and transparent conductive layers 21c and 21d have been formed in the transparent conduction formation layer formation step, and thereafter, the inorganic insulating film 22 is subjected to photolithography, wet etching or dry etching, resist removal, and cleaning, thereby forming contact holes 22aca and 22acb, and the groove G in a grid pattern along the vicinity of regions each in which the pixel electrode 23a is formed so that part of the transparent conduction formation layer 21ba is exposed, thereby forming a second protective insulating film 22a, as shown in FIG. 11(a). At that time, the transparent electrode 21a, the transparent conduction formation layer 21ba, and the transparent conductive layer 21c and 21d formed in the transparent conduction formation layer formation step are crystallized by the annealing at the time of the film formation by the CVD method.

<Pixel Electrode Formation Step>

Initially, a second transparent conductive film (thickness: approximately 30 nm to 150 nm) 23, such as an ITO film etc., is formed by, e.g., a sputtering method on the entire substrate on which the transparent conductive layer 22a formed in the second protective insulating film formation step has been formed, and thereafter, the second transparent conductive film 23 is annealed at a temperature of 150° C. or more, thereby crystallizing the second transparent conductive film 23, as shown in FIG. 15(a).

Subsequently, the crystallized second transparent conductive film 23 is subjected to photolithography, wet etching, resist removal, and cleaning, thereby forming the pixel electrode 23a, a gate terminal 23b, a source terminal (23c), as shown in FIG. 15(b). At that time, the transparent conduction formation layer 21ba exposed from the second protective insulating film 22a is removed toward the side by wet etching, and the patterned edge moves back from a sidewall W of a groove G of the second protective insulating film 22a, thereby forming the transparent conductive layer 21b.

In this way, the active matrix substrate 30a of this embodiment can be fabricated.

As described above, according to the active matrix substrate 30a, and the method for fabricating the same in this embodiment, in the first protective insulating film formation step, the first protective insulating film 20a is formed on the TFT 5a which has been formed on an insulating substrate 10 in the TFT formation step, and in the transparent conduction formation layer formation step, the first transparent conductive film 21 is formed to cover the first protective insulating film 20a, and thereafter, the first transparent conductive film 21 is patterned, thereby forming the transparent conduction formation layer 21ba, and in the second protective insulating film formation step, the inorganic insulating film 22 is formed to cover the transparent conduction formation layer 21ba, and thereafter, the groove G is formed along the vicinity of the regions each in which the pixel electrode 23a on the inorganic insulating film 22 is disposed, thereby forming the second protective insulating film 22a so that the part of the transparent conduction formation layer 21ba is exposed, and in the pixel electrode formation step, the second transparent conductive film 23 is formed on the second protective insulating film 22a, and thereafter, when the second transparent conductive film 23 is patterned, the transparent conduction formation layer 21ba exposed form the second protective insulating film 22a is etched, thereby the transparent conduction formation layer 21ba to move back from the sidewall W of the groove G of the second protective insulating film 22a to form the pixel electrode 23a and the transparent conductive layer 21b. Therefore, the second protective insulating film 22a formed in the second protective insulating film formation step is disposed to cover the transparent conductive layer 21b formed in the pixel electrode formation step by forming overhangs. In the pixel electrode formation step, the second transparent conductive film 23 is etched, and the transparent conduction formation layer 21ba exposed form the second protective insulating film 22a is etched to allow the transparent conduction formation layer 21ba to move back from the sidewall W of the groove G of the second protective insulating film 22a, whereby the etchant used for the wet etching can easily enter the groove G of the second protective insulating film 22a, and therefore, it becomes difficult to leave the second transparent conductive film 23 located in the groove G of the second protective insulating film 22a. This makes it difficult to conduct adjoining ones of the pixel electrodes 23a on the second protective insulating film 22a to each other through the second transparent conductive film 23 in the groove G of the second protective insulating film 22a, and therefore, it is possible to reliably reduce or prevent a short circuit between the adjoining ones of the pixel electrodes 23a.

According to the active matrix substrate 30a and the method for fabricating the same in this embodiment, since the first transparent conductive film 21 and the second transparent conductive film 23 are made of the ITO film, and the first transparent conduction formation layer 21ba and the second transparent conductive film 23 have crystallinity, the wet etching of the transparent conduction formation layer 21ba and the wet etching of the second transparent conductive film 23 can be performed using the same etchant in the pixel electrode formation step, and therefore, the fabrication steps can be reduced.

While this embodiment has illustrated the fabrication method of applying the technique of patterning the transparent conductive layers 21b and the pixel electrodes 23a in the same step to the fabrication method of the first embodiment, the technique of patterning the transparent conductive layers 21b and the pixel electrodes 23a in the same step may be applied to the fabrication method of the second embodiment.

While this embodiment has illustrated the method for fabricating the active matrix substrate by using an ITO film as a transparent conductive film, and crystallization is performed by an anneal treatment, an IZO film whose etching characteristics do not vary by annealing may be used as a transparent conductive film, and the anneal treatment may be omitted.

### Fourth Embodiment of the Invention

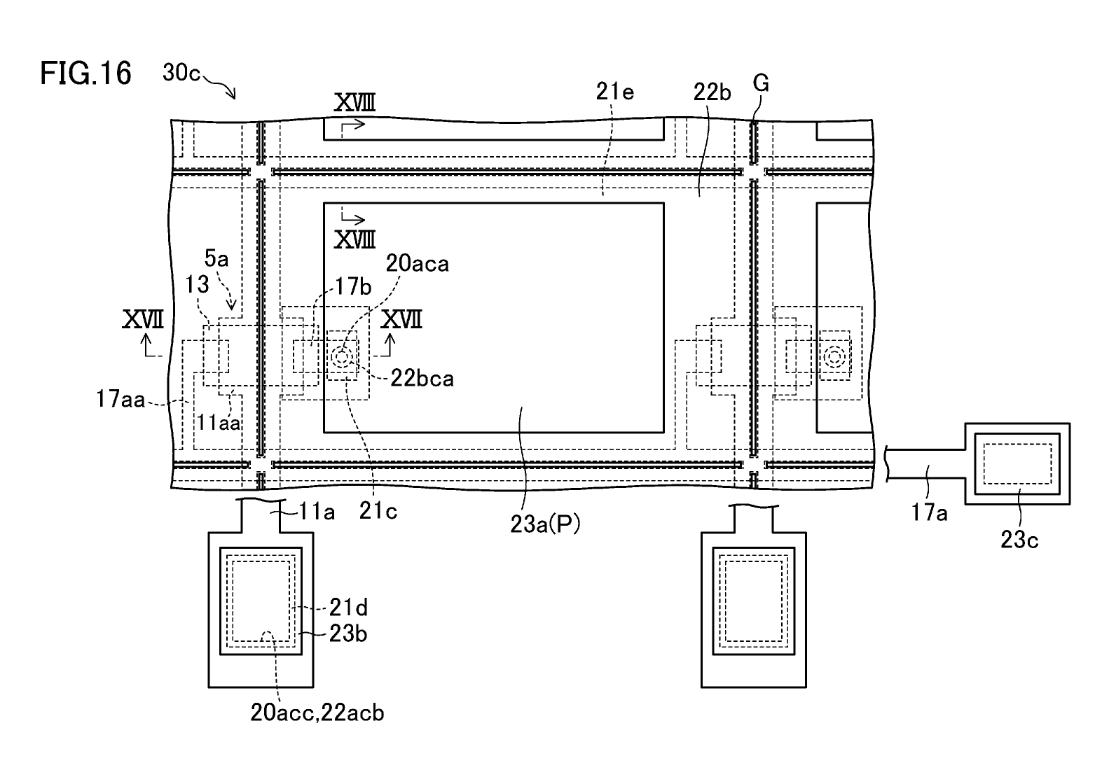

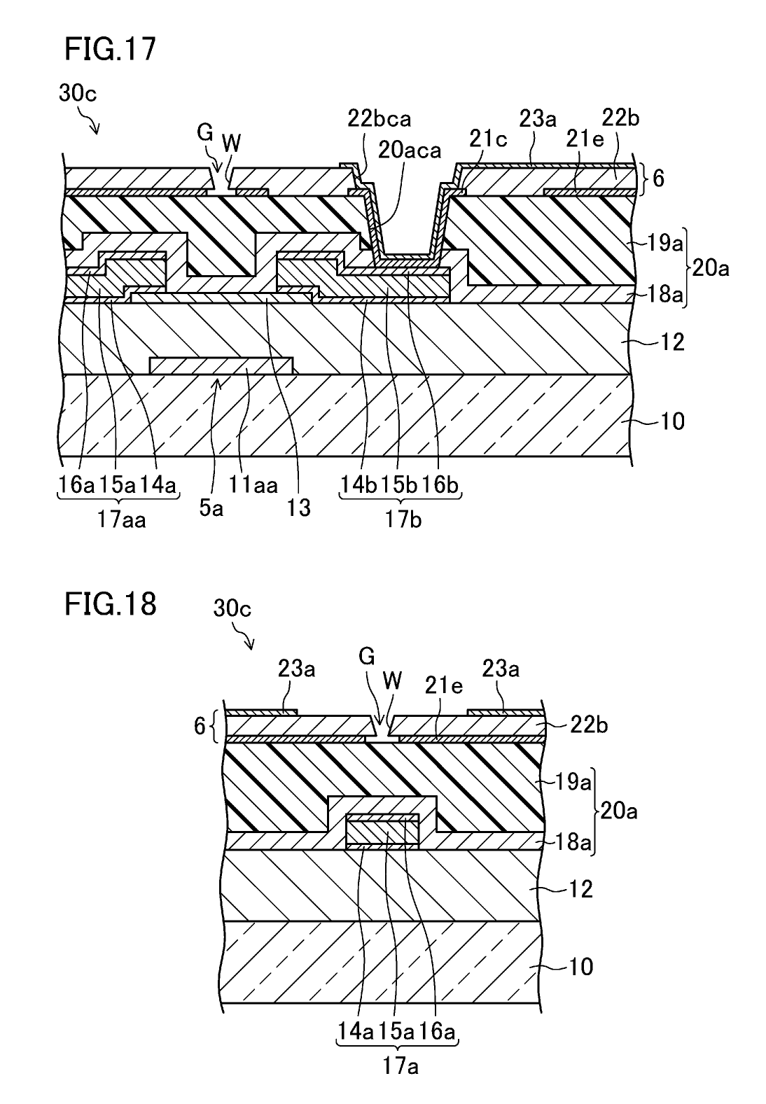

FIGS. 16-18 illustrate a fourth embodiment of the active matrix substrate, the method for fabricating the same, and the liquid crystal display panel according to the present invention. Specifically, FIG. 16 is a plan view of an active matrix substrate 30c according to this embodiment. FIGS. 17 and 18 are cross-sectional views of the active matrix substrate 30c respectively taken along the line XVII-XVII, and the line XVIII-XVIII of FIG. 16.

While the first to third embodiments have illustrated the active matrix substrates 30a and 30b in which each of the transparent conductive layers 21b is provided for each pixel P, this embodiment will illustrate the active matrix substrate 30c in which a transparent conductive layer 21e is continuously formed across all of the pixels P.

The liquid crystal display panel of this embodiment includes the active matrix substrate 30c and a counter substrate (40) provided to face each other, a liquid crystal layer (45) provided between the active matrix substrate 30c and the counter substrate (40), and a frame-shaped sealing material (46) provided to bond the active matrix substrate 30c and the counter substrate (40) together, and to enclose the liquid crystal layer (45) between the active matrix substrate 30c and the counter substrate (40).

The active matrix substrate 30c includes, as shown in FIG. 16, an insulating substrate 10, a plurality of capacitor lines 11b each provided between the gate lines 11a to extend in parallel to each other, a plurality of source lines 17a provided to extend in parallel to each other along a direction perpendicular to the gate lines 11a, a plurality of TFTs 5a, as a switching element, each provided at an interconnection portion between the gate line 11a and the source line 17a (one TFT 5a is provided for each pixel P), a first protective insulating film 20a (see FIGS. 17 and 18) provided on the TFTs 5a, a second protective insulating film 22b formed on the first protective insulating film 20a, a plurality of pixel electrodes 23a arranged in a matrix pattern on the second protective insulating film 22b, and an alignment film (not shown) provided to cover the pixel electrodes 23a.

As shown in FIGS. 16 and 17, the drain electrode 17b of the TFT 5a is connected to the pixel electrode 23a through a contact hole 20aca formed in the first protective insulating film 20a, a transparent conductive layer 21c formed inside the contact hole 20aca, and a contact hole 22bca formed in the second protective insulating film 22b.

As shown in FIGS. 16-18, in the second protective insulating film 22b, segment-shaped grooves G are formed along the vicinity of each of the pixel electrodes 23a so that the first protective insulating film 20a is exposed.

As shown in FIG. 16, the transparent conductive layer 21e continuously formed across all of the pixels P and including cutout patterns formed in linear shapes along the grooves G of the second protective insulating film 22b is provided between the first protective insulating film 20a and the second protective insulating film 22b.

As shown in FIGS. 16-18, the transparent conductive layer 21e has inner peripheral edges each provided along the groove G of the second protective insulating film 22b to be exposed from a sidewall W of the groove G while being recessed from the sidewall W of the groove G. As shown in FIGS. 16-18, the transparent conductive layer 21e overlaps each of the pixel electrodes 23a through the second protective insulating film 22b, thereby constituting the auxiliary capacitor 6.

The active matrix substrate 30c having the above configuration can be fabricated by a fabrication method similar to the fabrication method described in the first embodiment.

As described above, according to the active matrix substrate 30c, and the method for fabricating the same in this embodiment, as well as the first embodiment, the transparent conductive layer 21e disposed between the first protective insulating film 20a located above the TFTs 5b and the second protective insulating film 22a located under the pixel electrodes 23a is provided along the grooves G of the second protective insulating film 22b to be exposed from a sidewall W of the groove G while being recessed from the sidewall W of the groove G. Therefore, it is possible to reliably reduce or prevent a short circuit between the adjoining ones of the pixel electrodes 23a. Since a capacitor line having light-shielding properties in each pixel P is not disposed, it is possible to improve an aperture ratio in each pixel P.

### Fifth Embodiment of the Invention

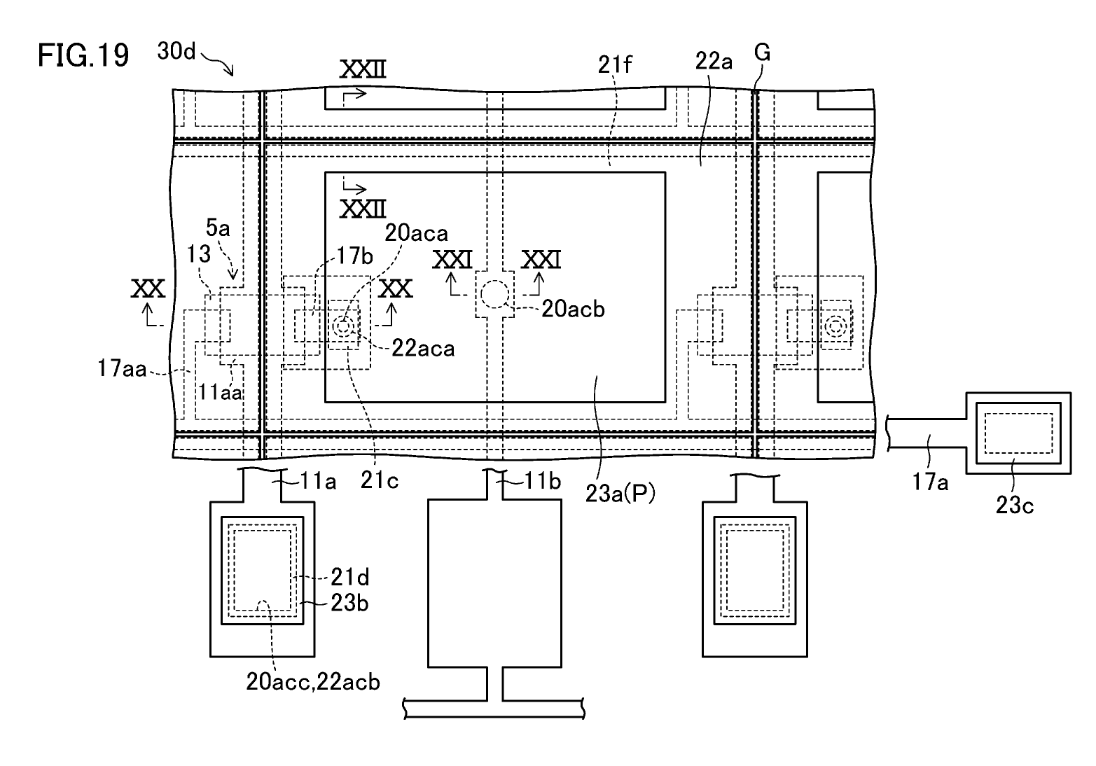

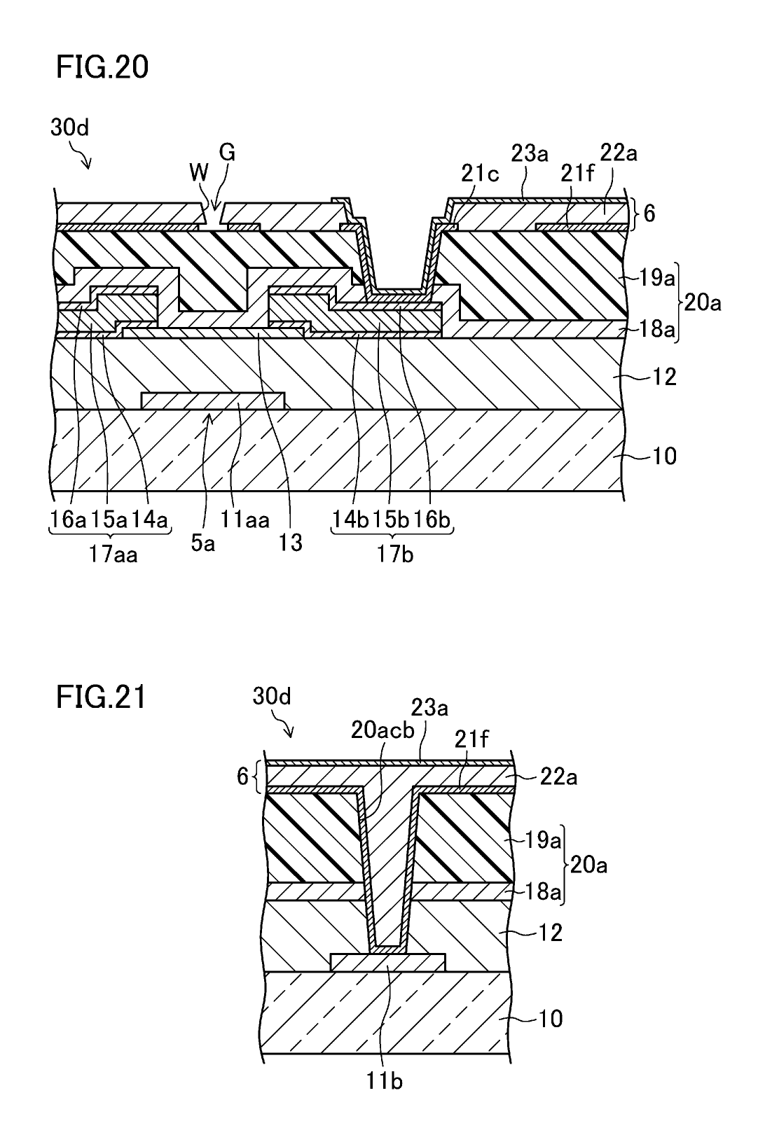

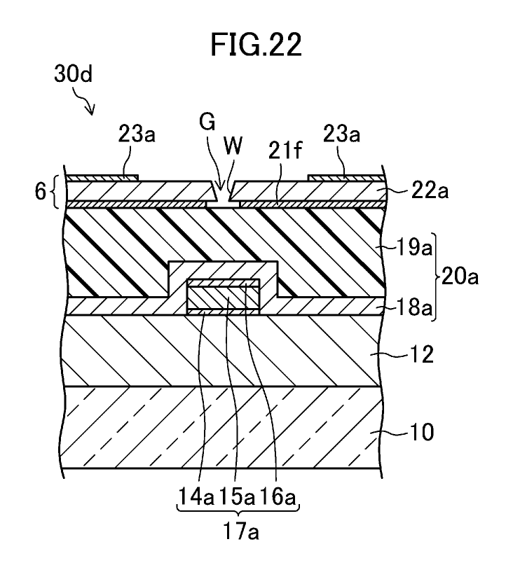

FIGS. 19-22 illustrate a fifth embodiment of the active matrix substrate, the method for fabricating the same, and the liquid crystal display panel according to the present invention. Specifically, FIG. 19 is a plan view of an active matrix substrate 30d according to this embodiment. FIGS. 20, 21 and 22 are cross-sectional views of the active matrix substrate 30d respectively taken along the line XX-XX, the line XXI-XXI, and the line XXII-XXII of FIG. 19.

While the first-third embodiments have illustrated the active matrix substrates 30a and 30b in which each of the frame-shaped transparent conductive layers 21b is provided for each pixel P and the transparent electrode 21a is provided within the frame, this embodiment will illustrate the active matrix substrate 30d in which a transparent conductive layer 21f is provided for each pixel P, the transparent conductive layer 21f being constituted by the transparent electrode 21a and the transparent conductive layer 21b which are integrally connected together.

The liquid crystal display panel of this embodiment includes the active matrix substrate 30d and a counter substrate (40) provided to face each other, a liquid crystal layer (45) provided between the active matrix substrate 30d and the counter substrate (40), and a frame-shaped sealing material (46) provided to bond the active matrix substrate 30d and the counter substrate (40) together, and to enclose the liquid crystal layer (45) between the active matrix substrate 30d and the counter substrate (40).

The active matrix substrate 30d includes, as shown in FIG. 19, an insulating substrate 10, a plurality of gate lines 11a provided on the insulating substrate 10 to extend in parallel to each other, a plurality of capacitor lines 11b each provided between the gate lines 11a to extend in parallel to each other, a plurality of source lines 17a provided to extend in parallel to each other along a direction perpendicular to the gate lines 11a, a plurality of TFTs 5a, as a switching element, each provided at an interconnection portion between the gate line 11a and the source line 17a (one TFT 5a is provided for each pixel P), a first protective insulating film 20a (see FIGS. 20-22) provided on the TFTs 5a, a second protective insulating film 22a formed on the first protective insulating film 20a, a plurality of pixel electrodes 23a arranged in a matrix pattern on the second protective insulating film 22a, and an alignment film (not shown) provided to cover the pixel electrodes 23a.

As shown in FIGS. 19-22, in the second protective insulating film 22a, a groove G is formed in a grid pattern along the vicinity of the pixel electrodes 23a so that the first protective insulating film 20a is exposed.

As shown in FIGS. 19-22, a substantially rectangular shaped transparent conductive layer 21f having an opening is provided between the first protective insulating film 20a and the second protective insulating film 22a in each pixel P, and in the opening, a transparent conductive layer 21c is provided to overlap the contact hole 20aca of the first protective insulating film 20a, and the contact hole 22aca of the second protective insulating film 22a.

As shown in FIGS. 19-22, the transparent conductive layer 21f has outer peripheral edges each provided along the groove G of the second protective insulating film 22b to be exposed from a sidewall W of the groove G while being recessed from the sidewall W of the groove G. As shown in FIGS. 19-22, the transparent conductive layer 21f is connected to the capacitor line 11b through a contact hole 20acb formed in the gate insulating film 12 and the first protective insulating film 20a, and overlap the pixel electrode 23a through the second protective insulating film 22a, thereby constituting the auxiliary capacitor 6.

The active matrix substrate 30d having the above configuration can be fabricated by a fabrication method similar to the fabrication method described in the first embodiment.

As described above, according to the active matrix substrate 30d, and the method for fabricating the same in this embodiment, as well as the first embodiment, the transparent conductive layer 21f disposed between the first protective insulating film 20a located above the TFTs 5b and the second protective insulating film 22a located under the pixel electrodes 23a is provided along the groove G of the second protective insulating film 22a to be exposed from the sidewall W of the groove G while being recessed from the sidewall W of the groove G. Therefore, it is possible to reliably reduce or prevent a short circuit between the adjoining ones of the pixel electrodes 23a.

The above embodiments have illustrated the In—Ga—Zn—O-based oxide semiconductor layer. The present invention is also applicable to, for example, oxide semiconductor layers, such as In—Si—Zn—O-based oxide semiconductor layers, In—Al—Zn—O-based oxide semiconductor layers, Sn—Si—Zn—O-based oxide semiconductor layers, Sn—Al—Zn—O-based oxide semiconductor layers, Sn—Ga—Zn—O-based oxide semiconductor layers, Ga—Si—Zn—O-based oxide semiconductor layers, Ga—Al—Zn—O-based oxide semiconductor layers, In—Cu—Zn—O-based oxide semiconductor layers, Sn—Cu—Zn—O-based oxide semiconductor layers, Zn—O-based oxide semiconductor layers, In—O-based oxide semiconductor layers, In—Zn—O-based oxide semiconductor layers, etc., and silicon semiconductors, such as amorphous silicon, polysilicon, etc.

While the above embodiments have illustrated the gate insulating film, the lower protective insulating film, and the second protective insulating film each having a single layer structure, the gate insulating film, the lower protective insulating film, and the second protective insulating film may have a multilayer structure.

While the above embodiments have illustrated the TFT as a switching element, the present invention is also applicable to other switching elements, such as metal insulator metal (MIM) elements etc.

The above embodiments have illustrated the TFT substrate in which the electrode of the TFT connected to the pixel electrode serves as a drain electrode. The present invention is also applicable to an active matrix substrate in which an electrode of a TFT connected to the pixel electrode is referred to as a source electrode.

### INDUSTRIAL APPLICABILITY

As described above, the present invention can reliably reduce or prevent a short circuit between adjoining pixel electrodes by use of the configuration of the transparent auxiliary capacitor, and therefore, the present invention is useful for liquid crystal displays panel having a high aperture ratio and high luminance, and active matrix substrates constituting such liquid crystal display panels.

### DESCRIPTION OF REFERENCE CHARACTERS

G Groove
P Pixel
W Sidewall
5a, 5b TFT (Switching Element)
6 Auxiliary Capacitor
20a First Protective Insulating Film
21 First Transparent Conductive Film
21a Transparent Electrode
21b, 21e, 21f Transparent Conductive Layer
21ba Transparent Conduction Formation Layer
22 Inorganic Insulating Film
22a, 22b Second Protective Insulating Film
23 Second Transparent Conductive Film
23a Pixel Electrode
30a-30d Active Matrix Substrate
40 Counter Substrate
45 Liquid Crystal Layer
50 Liquid Crystal Display Panel

1. An active matrix substrate, comprising:
a plurality of pixels arranged in a matrix pattern;
a plurality of switching elements each provided for a corresponding one of the plurality of pixels;
a first protective insulating film provided on the plurality of switching elements;
a transparent conductive layer provided on the first protective insulating film;
a second protective insulating film provided on the transparent conductive layer; and
a plurality of pixel electrodes arranged in a matrix pattern on the second protective insulating film, and each connected to a corresponding one of the plurality of switching elements,
wherein
a groove is formed in the second protective insulating film along a vicinity of a corresponding one of the plurality of pixel electrodes so that part of the first protective insulating film is exposed, and
the transparent conductive layer is provided along the groove of the second protective insulating film to be exposed from a sidewall of the groove while being recessed from the sidewall of the groove.

2. The active matrix substrate of claim 1, wherein
the transparent conductive layer overlaps the plurality of pixel electrodes through the second protective insulating film, thereby constituting an auxiliary capacitor.

3. The active matrix substrate of claim 1, wherein
the transparent conductive layer comprises a plurality of transparent conductive layers each independently provided for a corresponding one of the plurality of pixels, and each overlapping a corresponding one of the plurality of pixel electrodes through the second protective insulating film, thereby constituting an auxiliary capacitor.

4. The active matrix substrate of claim 1, wherein
the transparent conductive layer comprises a plurality of transparent conductive layers each provided for a corresponding one of the plurality of pixels in a frame shape,
a transparent electrode is provided within each of the transparent conductive layers between the first protective insulating film and the second protective insulating film, and
the transparent electrode overlaps a corresponding one of the plurality of pixel electrodes through the second protective insulating film, thereby constituting an auxiliary capacitor.

5. The active matrix substrate of claim 1, wherein
the transparent conductive layer is thicker than each of the plurality of pixel electrodes.

6. A method for fabricating an active matrix substrate including a plurality of pixels arranged in a matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in a matrix pattern on the second protective insulating film, and each connected to a corresponding one of the plurality of switching elements,
the method comprising:
a switching element formation step of forming the plurality of switching elements on a substrate;
a first protective insulating film formation step of forming the first protective insulating film on the plurality of switching elements which have been formed;
a transparent conduction formation layer formation step of forming a first transparent conductive film to cover the first protective insulating film which have been formed, and then, patterning the first transparent conductive film, thereby forming a transparent conduction formation layer serving as the transparent conductive layer;
a second protective insulating film formation step of forming an insulating film to cover the transparent conduction formation layer, and then, forming a groove along a vicinity of regions each in which each of the plurality of pixel electrodes in the insulating film is disposed, thereby forming the second protective insulating film so that part of the transparent conduction formation layer is exposed;
a transparent conductive layer formation step of etching the part of the transparent conduction formation layer exposed from the second protective insulating film which has been formed to allow the transparent conduction formation layer to move back from a sidewall of the groove of the second protective insulating film, thereby forming the transparent conductive layer; and
a pixel electrode formation step of forming a second transparent conductive film on the second protective insulating film on the transparent conductive layer which has been formed, and then, patterning the second transparent conductive film, thereby forming the plurality of pixel electrodes.

7. A method for fabricating an active matrix substrate including a plurality of pixels arranged in a matrix pattern, a plurality of switching elements each provided for a corresponding one of the plurality of pixels, a first protective insulating film provided on the plurality of switching elements, a transparent conductive layer provided on the first protective insulating film, a second protective insulating film provided on the transparent conductive layer, and a plurality of pixel electrodes arranged in a matrix pattern on the second protective insulating film, and each connected to a corresponding one of the plurality of switching elements,
the method comprising:
a switching element formation step of forming the plurality of switching elements on a substrate;
a first protective insulating film formation step of forming the first protective insulating film on the plurality of switching elements which have been formed;
a transparent conduction formation layer formation step of forming a first transparent conductive film to cover the first protective insulating film which have been formed, and then, patterning the first transparent conductive film, thereby forming a transparent conduction formation layer serving as the transparent conductive layer;
a second protective insulating film formation step of forming an insulating film to cover the transparent conduction formation layer, and then, forming a groove along a vicinity of regions each in which each of the plurality of pixel electrodes in the insulating film is disposed, thereby forming the second protective insulating film so that part of the transparent conduction formation layer is exposed;
a pixel electrode formation step of forming a second transparent conductive film on the second protective insulating film which has been formed, and then, etching the part of the transparent conduction formation layer exposed from the second protective insulating film when patterning the second transparent conductive film to allow the transparent conduction formation layer to move back from a sidewall of the groove of the second protective insulating film, thereby forming the plurality of pixel electrodes and the transparent conductive layer.

8. The method of claim 6, wherein
in the pixel electrode formation step, the second transparent conductive film located in the groove of the second protective insulating film is removed.

9. The method of claim 6, wherein
the first transparent conductive film is thicker than the second transparent conductive film.

10. The method of claim 7, wherein
the first transparent conductive film and the second transparent conductive film are made of a compound of indium oxide and tin oxide, and
the transparent conduction formation layer and the second transparent conductive film have crystallinity.

11. The method of claim 7, wherein
the first transparent conductive film and the second transparent conductive film are made of a compound of indium oxide and zinc oxide.

12. (canceled)

13. A liquid crystal display panel, comprising:
an active matrix substrate according to claim 1,
a counter substrate provided to face to the active matrix substrate, and
a liquid crystal layer provided between the active matrix substrate and the counter substrate.
